(19) United States
(12) Patent Application Publication
(10) Pub. No.: US 2026/0035797 A1
(43) Pub. Date: Feb. 5, 2026

(54) PLASMA COATING WITH PARTICLES

(71) Applicant: XEFCO PTY LTD, Eveleigh, New South Wales (AU)

(72) Inventors: Thomas HUSSEY, Drummoyne, New South Wales (AU); Scott WHITBY, Kingsville, Victoria (AU); Zhiqiang CHEN, Werribee, Victoria (AU); Weiwei LEI, Waurn Ponds, Victoria (AU); Salumeh ISSAZADEH, Waurn Ponds, Victoria (AU); Qingrui KONG, Waurn Ponds, Victoria (AU)

(21) Appl. No.: 19/100,077

(22) PCT Filed: Aug. 1, 2023
(86) PCT No.: PCT/AU2023/050719

§ 371 Date: Jan. 30, 2025

(30) Foreign Application Priority Data
Aug. 1, 2022 (AU) 2022902159

(51) Int. Cl. C23C 16/50; A01N 25/12; A01P 1/00

(52) U.S. Cl. CPC C23C 16/50; A01N 25/12; A01P 1/00

(57) ABSTRACT

A coating applied to an article which includes a pigment or a dispersion. The coating comprising an upper side and a lower side. The coating being applied to at least one surface of the article: and wherein the coating is formed from a monomer and a nanoparticle which have passed through a plasma such that a plasma polymerised coating have been formed.

### TECHNICAL FIELD

The present invention may be directed towards a method and coating product. More particularly the present invention may be directed towards a method for manufacturing a coating comprising a particle, and a product which comprises a particle, in which the coating is formed, at least in part, by a plasma polymerisation process.

### BACKGROUND

The development of superhydrophobic fabrics was accomplished by coating the surface of the fabric with a material to minimise the surface free energy. The theory of modifying morphology to maintain low surface tension is known.

Many methods for achieving a superhydrophobic surface on textiles rely on chemical solution treatment. The chemical surface must be modified with an oxidising agent, such as chromic acid, and liquid reagents in order to generate reactive functional groups.

However, in view of the number of potential methods for generating a superhydrophobic coating there is a need to provide for a less energy intensive method, in addition to providing for a method which can reduce the chemistry required to effectively provide for a superhydrophobic coating.

Particles may have utility with a wide range of applications, however the ability for these particles to be provided within a coating is generally expensive and does not yield a desirable final coating as they may be unreasonably thick, reduce handfeel, provide an undesirable tactile finish or generally do not provide for a durable coating.

Other functionalisations or coatings may also be desired which include nanoparticles. As nanoparticles may be organic or inorganic, a number of properties can be imparted to a coating with the addition of nanoparticles or other compounds.

Any discussion of the prior art throughout the specification should in no way be considered as an admission that such prior art is widely known or forms part of common general knowledge in the field.

### SUMMARY

### Problems to be Solved

It may be advantageous to provide for a substrate with a viral-inhibiting coating.

It may be advantageous to provide for a substrate with a nanoparticle coating which can be applied via a plasma deposition.

It may be advantageous to provide for a substrate with an oligodynamic property.

It may be advantageous to provide for a coating which can be used to provide for multiple functionalities.

It may be advantageous to provide for a coating which can fix a particle in a desired location relative to an article or substrate.

It may be advantageous to provide for a coating method which can fix particles to a substrate or article in a desired array.

It may be advantageous to provide for a coating which can improve fixation and/or embedding of particles.

It may be advantageous to provide for a functional coating which comprises a desired surface roughness.

It may be advantageous to provide for a coating which can change functionality with exposure to light.

It may be advantageous to provide for a coating which includes one or more nanoparticles.

It may be advantageous to provide for a method of coating an article with a nanoparticle and a protective coating simultaneously.

It is an object of the present invention to overcome or ameliorate at least one of the disadvantages of the prior art, or to provide a useful alternative.

### Means for Solving the Problem

In a first aspect there may be provided a coating for an article. The coating comprising an upper side and a lower side. The coating may be applied to at least one surface of the article; and wherein the coating may be formed from a monomer and a nanoparticle which have passed through a plasma. Optionally, the nanoparticles may be microparticle size if the microparticle can be carried with a carrier fluid, or by a monomer.

Preferably, the monomer may be at least partly polymerised when introduced into the plasma. Preferably, the nanoparticle and the monomer may be a dispersion or sol-gel solution which is atomised before being introduced into the plasma. Preferably, the monomer and the nanoparticle are passed through a plasma before being deposited onto the article. Preferably, more than one species of nanoparticle may be within the coating. Preferably, the upper side of the coating may be exposed to atmosphere. Preferably, the upper side of the coating may be adapted to be in contact with one or more pathogens. Preferably, the nanoparticle may have at least one of a pathogen inhibiting property, and an oligodynamic property.

In yet another aspect of there may be provided a method for treating an article with a pathogen inhibiting layer. The method may comprise positioning an article relatively below a treatment module. Local atmosphere may be purged between the article and the treatment module. A plasma fluid may be supplied to an electrode region of the treatment module, the electrode region may comprise two or more electrodes. The plasma gas may be ignited to form a plasma in the electrode region; and supplying at least one of a monomer and a nanoparticle to the plasma in the electrode region, such that the monomer may be polymerised by the plasma and the nanoparticles being fixed to the article by polymerisation of the monomer as it forms a coating on the article.

Preferably, the nanoparticles may be adapted release ions to interfere with the persistence of a pathogen contacting the coating. Preferably, the nanoparticles may be distributed throughout the thickness of the coating. Preferably, the treatment module may identify an article below the electrodes and activates electrodes corresponding to the size of the article. Preferably, the nanoparticles may be carried by a carrier fluid to the article. Preferably, the carrier fluid may be an aerosol, a vapour, liquid or gas. Preferably, a gas aperture may be adapted to eject the monomer and nanoparticle into the plasma region and onto the article.

In the context of the present invention, the words “comprise”, “comprising” and the like are to be construed in their inclusive, as opposed to their exclusive, sense, that is in the sense of “including, but not limited to”.

The invention is to be interpreted with reference to the at least one of the technical problems described or affiliated with the background art. The present aims to solve or ameliorate at least one of the technical problems and this may result in one or more advantageous effects as defined by this specification and described in detail with reference to the preferred embodiments of the present invention.

### BRIEF DESCRIPTION OF THE FIGURES

FIG. 1 illustrates an isometric view of an embodiment of a system for treating an article;

FIG. 2 illustrates a side view of an embodiment of the system which includes a roll-to-roll device;

FIG. 3 illustrates a schematic view of an embodiment of a system for treating an article;

FIG. 4A illustrates a side view of an embodiment of a treatment module which can be used to apply a coating to an article;

FIG. 4B illustrates a side view of an embodiment of a treatment module showing a number of plasma regions or plasma effects which can be created;

FIG. 5A illustrates a sectional view of an embodiment of an electrode sheath of an electrode;

FIG. 5B illustrates a sectional view of another embodiment of an electrode sheath of an electrode;

FIG. 5C illustrates a sectional view of a further embodiment of an electrode sheath of an electrode;

FIG. 6 illustrates a side view of an article with a coating applied which comprises nanoparticles;

FIG. 7 illustrates a side view of an article with a coating applied comprising nanoparticles and a second coating;

FIG. 8 illustrates a side view of an article with an alternating treatment applied which comprises nanoparticles in predetermined sections;

FIG. 9 illustrates a side view of an article with a treatment applied which comprises nanoparticles and a further coating optional coating;

FIG. 10 illustrates a schematic of an experimental setup used for validation of some embodiments;

FIG. 11 illustrates a the K/S value of colour change for experimental samples;

FIGS. 12A and 12B illustrates examples of possible HMDSO fragmentation.

### DESCRIPTION OF THE INVENTION

Preferred embodiments of the invention will now be described with reference to the accompanying drawings and non-limiting examples.

### LIST OF FEATURES

1 Article
10 System
11 Terminal
12 Frame
15 Chamber
20 Module
22 Housing
30 Power source
40 Fluid delivery system
45 Cooling system
50 Mixing chamber
55 Atomiser
60 Rollers
70 Recirculation System
80 Support
85 Pump system
90 Extraction system
95 Storage
100 Electrode
102 Core
104 Sheath
106 Channel
108 Fluid channel
110 Reaction gap
112 Plasma region
114 Gas tube
116 Aperture
118 Bias supply
120 Bias
130 Carrier fluid supply
140 Monomer supply
150 Nanoparticle supply
200 Substrate
202 Substrate upper surface
204 Substrate lower surface
210 First coating
212 First coating upper surface
214 First coating lower surface
216 Particles
220 Second coating
222 Second coating upper surface
224 Second coating lower surface
226 Particles

There is described herein a system for treatment and processing of materials, which may include substrates, sheets of materials, 3D objects, and irregular objects collectively referred to as “articles” 1. While any desired article 1 may be treated with the system 10, several embodiments may reference substrates or other planar articles. As such, it is not a limitation of the system to only be used in the treatment of substrates 1.

An isometric embodiment of a system 10 is illustrated in FIG. 1, in which an article 1 may be treated and/or processed. The system 10 illustrated comprise a number of treatment modules 20 which are used to treat a substrate 1. The treatment modules 20 may be shower head modules, spray modules, deposition modules, plasma modules, or any other treatment modules which can be used to activate a surface, or apply a coating to a surface. Each module 20 may be removably mounted in the system 10 and be used to pre-treat, treat, coat, cover, deposit, activate or perform any desired treatment process to an article 1. Preferably, the treatments imparted by a treatment module 20 comprise nanoparticles and/or microparticles which are deposited after passing from the head through a plasma and onto an article 1.

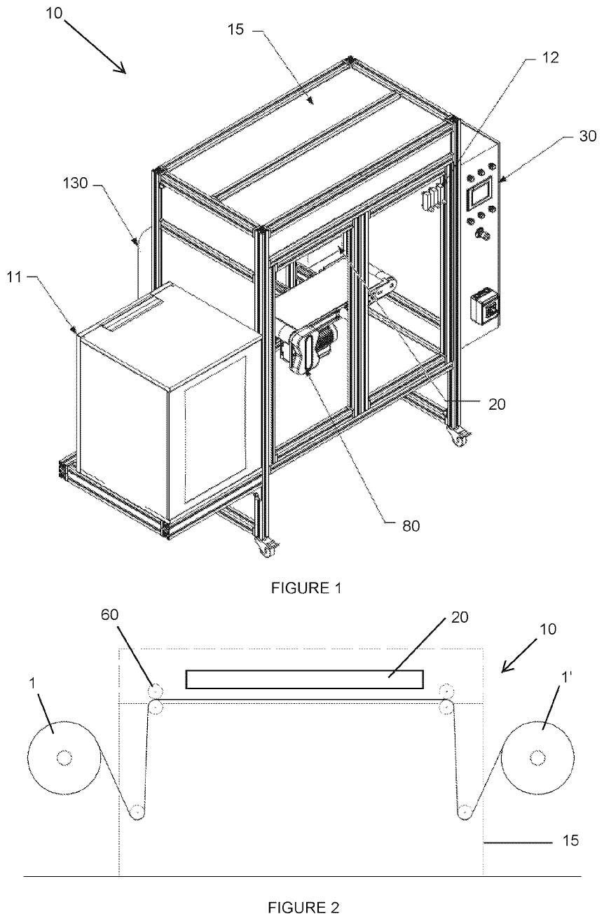

Articles 1 may be transported under a treatment head 20 by a transportation means. Any desired transportation means may be used, such as a conveyor, moving platform, rollers or any other predetermined means. An embodiment of a system 10 is illustrated in FIG. 2 in which rollers are used to transport a substrate article 1 through the chamber 15.

In another embodiment, articles 1 can be placed directly below the treatment module 20 and the article 1 may be treated without being transported from a first location to a second treatment location. This can be of particular use if single articles 1 are to be coated or treated, rather than a series of articles on a manufacturing line. In this manner, the system 10 may function as a sterilisation device, surface activation device or a selective treatment system.

The treatment modules 20 may allow for at least one of; physical alterations, chemical alterations, coatings, application of films, surface activations, sterilisation, polymerisation or other desired treatment process. The system 10 may comprise any number of modules to perform said treatments.

In a preferred embodiment, the system 10 is adapted to apply a pathogen inhibiting treatment to the article 1. The pathogen inhibiting treatment may include coatings or treatments which reduce the persistence of a pathogen on an article 1, and preferably kills, destroys, disrupts or inhibits the growth or life of a pathogen which comes into contact. A pathogen inhibiting treatment may be an antiviral coating or antipathogen treatment which may be configured for killing, disrupting or inhibiting specific viruses, bacteria, or microorganisms.

Antiviral and antipathogen treatments are well known within the medical field and have a wide range of applications. These treatments can be any number of treatments, functionalisations or coatings which can provide a generally toxic or adverse surface which can reduce the potential persistence of a pathogen thereon. At least one of a nanoparticle and/or a coating applied to the article can provide for the pathogen inhibiting treatment.

Pathogens according to this disclosure may include any one of; viruses, microorganisms, microbiological matter, and bacteria. Viruses which may be inhibited by the present disclosure may include at least one of the following group; Influenza, Measles, SARS-COV, SARS-COV-2, MERS-COV, Coronavirus, Mumps, Marburg, Ebola, Rubella, Rhinovirus, Poliovirus, Hepatitis A, Smallpox, Chicken-pox, Severe Acute Respiratory Syndrome virus or SARS virus (also referred to as SARS coronavirus), Human Immunodeficiency Virus (HIV) and associated non-human animal immunodeficiency retroviruses such as Simian Immunodeficiency Virus (SIV), Rotavirus, Norwalk virus and Adenovirus. Norwalk virus includes its surrogate Feline Calicivirus. Influenza viruses include both human and avian forms of the virus. In addition, bacteria associated with nosocomial infections may also be disrupted, inhibited or otherwise destroyed, and may include at least one bacteria causing at least one of the following infections; ventilator-associated pneumonia, Methicillin resistant Staphylococcus aureus, Candida albicans, Acinetobacter baumannii, Clostridium difficile, Tuberculosis, Urinary tract infection, Vancomycin-resistant Enterococcus and Legionnaires' disease.

The pathogen inhibiting treatment or coating can be applied by a plasma polymerisation method or plasma treatment method. In one embodiment, the pathogen inhibiting treatment is passed through a plasma region and then is subsequently deposited onto a surface. This is starkly different than conventional plasma treatment systems, wherein a plasma is used only to either activate a surface of an article to allow for a treatment to be applied using conventional methods, or is used to polymerise an existing coating on said article. The present method has a number of distinct advantages over the prior art.

It will be appreciated that conventional plasma treatment apparatuses also generally require a vacuum chamber or a chamber in which articles are treated. Plasma is not commonly used outside of an enclosed depressurised chamber as there are a number of problems associated with the use of plasma in non-vacuum chambers. One such problem is even distribution or uniform distribution of carrier fluids and monomers contained therein. Another problem is the introduction of fluids into a plasma region or reaction gap which may cause polymerisation of dangerous/undesired molecules or ionisation of molecules which may damage a substrate 1 being processed or impact the quality of the treatment. As such, the system modules 20 described herein may be used to address these issues.

In addition to the above, another significant issue with existing systems is that they are required to operate at a level of vacuum. Not only does it take a significant period of time to achieve a vacuum, but injecting an aerosol will generally increase the overall pressure within the vacuum chamber, which can lead to non-function of the system. Aerosols injected into a vacuum will also disperse and therefore not be able to be used. As such, the system and method of the present disclosure will have significant advantages over the known prior art.

It will be appreciated that in some embodiments the chamber 15 may have a pressure above atmospheric pressure when using gas delivery tubes or pressurised plasma fluids. This pressure may be in the range of 10 pascals to 1 MPa. In some embodiments the pressure may be in the range of 5 pascals to 100 pascals. In a specific embodiment, the chamber may be under a pressure of around 50 pascals ±20. Unlike conventional systems, the pressure is increased and rather than decreasing in the direction of vacuum pressure. As such, the system 10 may be adapted to function at atmospheric pressure or above atmospheric pressure.

Another significant advantage of this system 10 is that the use of aerosols to deliver a monomer and/or nanoparticle to a plasma region is possible for coating methods. Aerosols can be used to carry nanoparticles, salts, organic particles or inorganic particles to a plasma region or to another desired location within the chamber 15. As suggested before, an atomiser can be used to convert at least one fluid to vapour or aerosol. The vapour may be considered to be a form of “mist”, which may include one or more species of monomer and/or one or more species of nanoparticle. Optionally, microparticles can be dispersed within the mist formed by the atomiser.

Aerosols may be supplied to the chamber 15 via the fluid outlets and subsequently introduced, either directly or by gravity, into the plasma region. The aerosols can be directed towards a plasma region with at least 50% of the aerosol being passed through the plasma region and subsequently depositing onto a target area of the article 1. Using this method coatings of between 50 nm/min to 400 nm/min can be achieved. In some embodiments, a coating of between 100 nm to 300 nm can be achieved. In yet another embodiment, the deposition rate of a coating may be in the range of 150 nm/min.

In contrast, systems which utilise vacuum pressures are not able to achieve a coating as introduction of aerosols into a vacuum or near vacuum will result in higher pressures, and will also result in immediate dispersion of the aerosols throughout the vacuum chamber rather than delivery to a target area or plasma region 112. Even if a plasma region 112 could be provided at the outlet for the aerosol, which would result in a number of plasma irregularities upon ejection of the aerosol, the plasma polymerised aerosol or activated particles will then disperse into the chamber and will not flow in a desired direction. Other disadvantages are also known with conventional systems which utilise vacuum pressures or lower pressures.

In yet another embodiment, the nanoparticles may be entrained into an aerosol. In this way, powders or particulates of a desired size may be transported through the fluid system and to the plasma region 112. In another embodiment, a separate stream of nanoparticles or clusters may be provided, which mixes with the fluids exiting the outlets and directed toward the plasma region. Optionally, nanoparticles may be sprayed, knife coated, wiped, or ejected onto the article 1.

In the embodiment of FIG. 1, the system 10 also comprises frame 12 in which a chamber 15 is mounted. Within the chamber 15 an article 1 can be processed with a plasma treatment process, and a pathogen inhibiting, or nanoparticle coating can be applied thereto.

The chamber 15 is preferably sealable, and may form a fluid tight seal which can retain a desired local atmosphere. The chamber may optionally have an entry point and an exit point, such that planar articles 1 can be entered into the chamber 15 for treatment and taken out of the chamber after treatment. The entry point and an exit point preferably have a seal which prevents or substantially reduces the ingress of atmosphere outside of the chamber 15. Rollers 60 may be used to transport the article through the chamber 15, as can be seen in the embodiment of FIG. 2. A monomer supply 140 and/or sol-gel and/or dispersion supply may be in fluid communication with a mixing chamber 50 to allow for a carrier fluid 130 to be mixed with a monomer from a monomer supply 140 or sol-gel from the respective supplies. The carrier fluid may be an aerosol, a vapour, liquid or gas, for example. More than one monomer supply or dispersion supply may be present and selective introduction of fluids from within these supplies can be affected. The fluids from the mixing chamber can then be supplied to the circulation line (which may be a recirculation line if a recirculation system 70 is used), and the fluids can subsequently be supplied to the chamber 15. The carrier fluid is preferably a plasma gas which can be excited to form a plasma. For example, the carrier fluid may be an argon supply or another noble gas, which can be used to carry a monomer and/or dispersion to electrodes 100 of a treatment module 20. The electrodes 100 can be powered to energise the plasma gas to form a plasma which can be used to polymerise a monomer and/or excite/activate a nanoparticle.

A terminal 11 may be provided in communication with the system 10 which can be used to input variables, select fluids, monitor the chamber, and start and stop a process. Any desired terminal interface may be used, and the terminal may effect movement of one or more components of the system 10. Software may be executable and remotely updateable via the terminal. Preferably, a storage medium within the terminal 11 can be used to store data from processing and also store data in relation to errors or unauthorised use or access into the system.

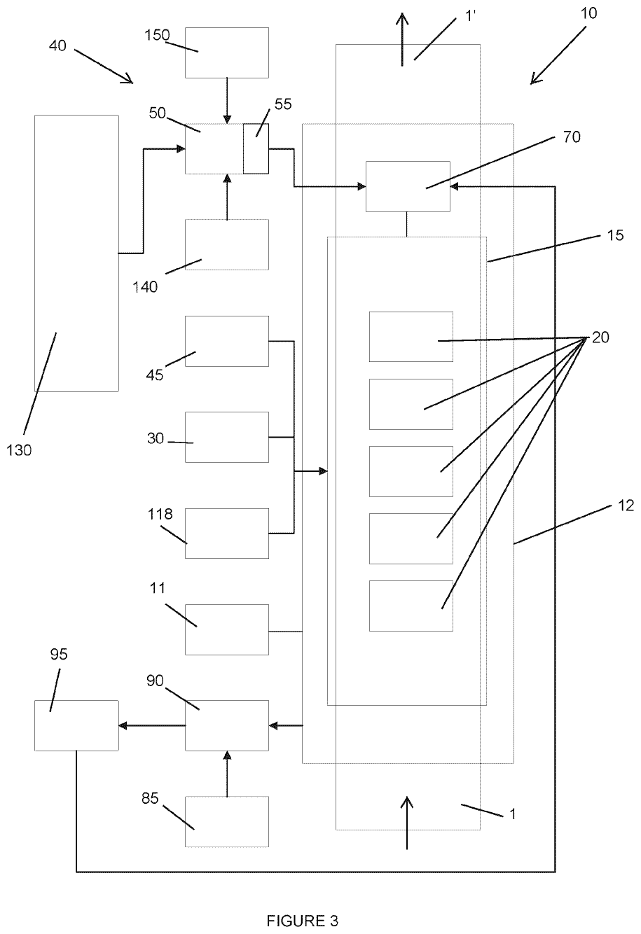

As seen in the schematic embodiment FIG. 3, an extraction booth or extraction system 90 may be provided to remove noxious fluids from the chamber 15, vent the chamber 15 or otherwise remove volatiles or atmosphere from the chamber. The extraction system 90 may be used to evacuate the ambient atmosphere within the chamber and allow for a controlled atmosphere to be injected or supplied into the chamber 15. A pump system 85 may also be associated with the extraction system 90 or with the chamber 15 directly which can be used to pump out local atmosphere within the chamber 15 when desired.

A power source 30 may be a generator or other mains powered device which can supply power to the system and components thereof. For example, the power supply can be connected to a treatment module within the chamber 15. A cooling system 75 may also be used to cool the system during use, and in particular may be used to cool at least one of the treatment modules 20, electrodes 100 and a bias plate 120. The article may be supported on a support 80, below which the bias 120 can be disposed. The bias may be a DC bias or other electrical bias which can assist with controlling plasma and/or directing flow of particles from a plasma region 112. This may further encourage polymerised monomer and/or nanoparticles therein to flow towards and deposit onto the article 1.

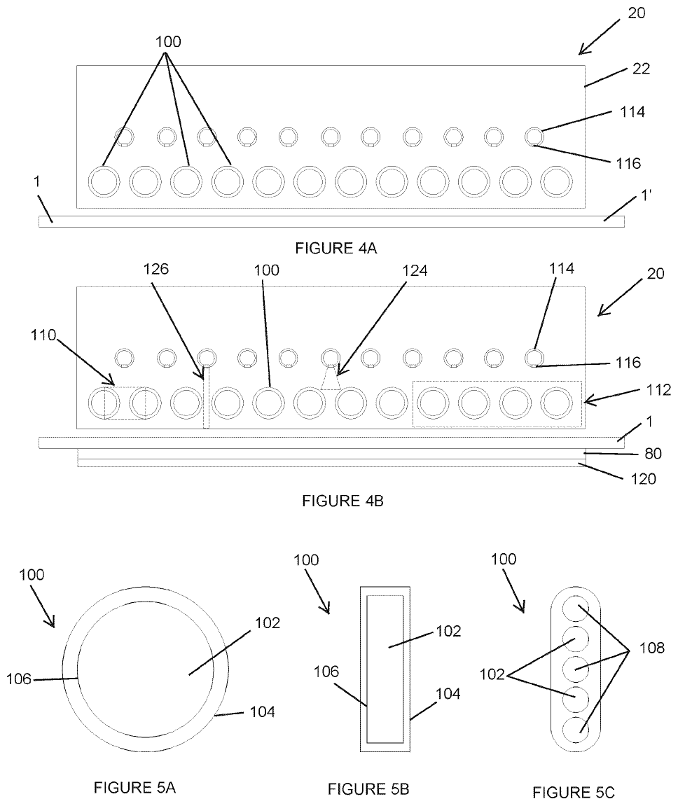

The system 10 comprises at least one pair of electrodes 100 which can be used to ignite or strike a plasma gas to form a plasma, which may be a dielectric barrier discharge. The space between the electrodes 100 may be referred to as a reaction gap, wherein a reaction between a voltage and a plasma fluid may be observed, or where polymerisation or fractionation of a monomer or polymer occurs. Fractionation of a monomer may be within a plasma region 112, which may be above, below or between electrodes, as is exemplified within FIG. 4B. A plasma region 112 is formed within a reaction gap 110 and may fill the entire reaction gap 110, or a portion thereof. The space between electrodes 100 may be in the range of 1 mm to 12 mm depending on a desired plasma density, and said space may be the reaction gap 110. The space between electrodes 100 may be from sheath to sheath of adjacent electrodes 100, or centre to centre spacing of adjacent electrodes 100. It will be appreciated if the spacing is sheath to sheath, the distance between core to core will be greater.

Dielectric barrier discharges are typically characterised by the presence of at least one dielectric barrier, such sheath 104 and a reaction gap 110 located between a respective pair of electrodes 100. Dielectric barrier discharges may have the ability of breaking chemical bonds, exciting atomic and molecular particles, and generating active particles such as free radicals. Dielectric barrier discharge systems may be referred to as; “non-thermal systems”, or “nonequilibrium systems”, or “cold plasma systems”.

In contrast to non-thermal systems, thermal plasmas have electrons and heavy particles at the same temperature, and are therefore in thermal equilibrium with each other. However, non-thermal plasmas are usually characterised as containing ions and uncharged particles (heavy particles) at lower temperatures than electrons. Since the temperatures of the heavy particles in the plasma remain relatively low, excluding any undesired polymer degradation, dielectric barrier discharge burners have been described as suitable for polymerization and deposition processes. The inherent advantage of dielectric barrier discharge systems over other conventional thermal plasma systems is that non-thermal plasma conditions can be easily set at or near atmospheric pressures, and may also be used to treat or polymerise monomers and/or polymers.

Using the system 10, various polymer coatings, polymeric films, nanoparticle coatings, and nanoparticle treatments can be deposited onto an article 1. Non-limiting examples of coating monomers may include at least one monomer elected from the following group; acetylene, ethylene, isoprene, hexamethyldisiloxane (HMDSO), tetraethyloxy silane (TEOS), tetraethyloxy silica, diethyl dimethyl siloxane, 1,3-butadiene, styrene, methyl styrene, tetrafluoroethylene (TFE), methane, ethane, propane, butane, pentane, hexane, cyclohexane, acetylene, ethylene, propylene, benzene, isoprene, hexamethyldisiloxane, tetraethyloxy silane, tetraethyloxy silane, diethyl dimethyl siloxane, 1,3-butadiene m, styrene, methyl methacrylate, tetrafluoroethylene, pyrrole, cyclohexane, 1-hexene, allyl amine, acetylacetone, ethylene oxide, glycidyl methacrylate, acetonitrile, tetrahydrofuran, ethyl acetate, acetic anhydride, aminopropyltrimethylene triethoxyethane triethoxyethanoethoxytethenethoxyethane triethoxyethanoethoxyethane triethoxyethanoethoxyethane triethoxyethanoethoxyethane triethoxyethanoethoxyethane triethoxyethanoethoxyethane triethoxyethanoethoxyethane triethoxyethanoethoxyethane triethoxyethanoethoxyethane triethoxyethanoethoxyethane triethoxyethanoethoxyethane triethoxyethanethoxyethanoethoxyethane triethoxyethanoethoxyethane triethoxyethanoethoxyethane triethoxyethanethoxytriethoxyethanoethoxyethanoethoxy ethanol, tricarbonyl (cyclooctatetraen) iron, dicarbonyl (methylcyclopentadienyl) iron, dimer dicarbonyl (dicyclopentadienyl) iron, cobalt cyclopentadienyl cobaltacetylacetonate, nickel acetylacetonate, dimeti-(2,4-pentan-dionates) gold (III), nickel carbonyl, iron carbonyl, tin acetylacetonate, indium acetylacetonate, indium-tetramethylheptanedionate.

In at least one embodiment, an organic and/or inorganic coating may be applied. Inorganic coating precursors include pure metals, metal salts, oxides, nitrides, carbides, or combinations thereof. In yet another embodiment, the system 10 may allow for various particles to be coated ranging in size from nanometre to micron. Coatings may be deposited by means of precursors that are either in a gaseous or liquid or solid state, but are preferably in a vaporised or aerosol state.

In addition, nanoparticles having a range of sizes from about 10 nm to about 100 nm can be used as components of a larger molecular structure, generally in the range of about 100 nm to 1,000 nm. For example, a nanoparticle may be surface coated to increase its size, be embedded in an acceptable carrier, or it may be entwined or added to other particles, or to other materials, which generate a larger particle. In certain embodiments in which at least one dimension of at least one nanoparticle within a solution of nanoparticles is below 50 nm to 100 nm, the surface of the nanoparticles may be coated with a non-conductive matrix of between 10 nm to 100 nm thick or more in order to increase that dimension or particle to 50 nm to 100 nm or more. This larger size can increase the supply of nanoparticles for deposition onto an article 1.

In yet another embodiment, the nanoparticles have optical absorption qualities of about 10 nm to about 10,000 nm, for example, 100 nm-500 nm. Optionally, the nanoparticles have optical absorption useful for excitation by standard laser devices or other light sources. For example, nanoparticles may be adapted to absorb wavelengths of approximately 755 nm, in the range of approximately 800 nm to 810 nm, or about 1,000 nm to 1,100 nm. Similarly, nanoparticles may also be adapted to absorb intense pulsed light in the range of about 500 nm to 1,200 nm.

The nanoparticles provided herein may generally contain a collection of non-assembled nanoparticles. By “non-assembled” nanoparticles, it is understood that the nanoparticles of said collection are not linked to each other through a physical force or chemical bond, either directly (particle-formula) or indirectly through an intermediary (for example, particle-cell-part, part-protein-part, part-analyte-part). In other embodiments, nanoparticle compositions are assembled in ordered matrices. In particular, said ordered matrices can include any three-dimensional matrix. In some embodiments, only part of the nanoparticles are assembled, for example, 5, 10, 15, 20, 25, 30, 35, 40, 45, 50, 55, 60, 65, 70, 75, 80, 86, 90, 95, 99% or more than 99% of the nanoparticles are assembled in an ordered array. The nanoparticles are assembled by attraction of van der Walls, a London force, a hydrogen bond, a dipole-dipole interaction, or a covalent bond, or a combination thereof.

The microparticles and nanoparticles have an average diameter of around 10 nm to 10 μm, and are distributed on the polymer surface at intervals of 10 nm to 3000 nm, structured as a function of the size of the particles applied.

In one embodiment, the plasma struck in the reaction gap 110 is formed at approximately room temperature and at about atmospheric pressure. In at least one embodiment it is preferred that the plasma generated in the plasma region 112 is an atmospheric-pressure plasma glow (APG). APG may be encouraged by introducing a monomer into a plasma region, or may be encouraged by using a Penning mixture. A monomer may be used as a low ionisation fluid which can form part of the Penning mixture with a plasma gas. In some embodiments, the plasma gas is an argon gas and the monomer selected for polymerisation has a lesser ionisation threshold. Excitation of a carrier fluid may occur before injection of a monomer.

Preferably cold atmospheric plasma (CAP) may be used to impart a desired pathogen inhibiting coating or other functional coating to an article 1. CAPs are partly ionised gases (with a typical ionization fraction of one ion or electron per a billion neutral atoms or molecules) producing a reactive mix by interacting with the surrounding air and being composed of electrons, ions, neutrons, excited atoms and molecules, reactive oxygen and nitrogen species, and UV light. Depending on the respective plasma source technology, carrier fluid, plasma operating parameters and set-up modalities, such as transportation mode and volume, the composition as well as the concentrations of the produced plasma species vary. This means, that CAPs can be “designed” to a certain extent and that different compositions of reactive species can be produced by changing plasma input parameters such as carrier fluids, voltages, frequencies and other parameters which can be used to influence a plasma density and/or formation.

The plasma may be generated by a discharge between electrodes 100 in which a plasma gas can be excited or ionised to form said plasma. Any predetermined method may be used to generate a plasma including; alternating current (AC) excitation, the direct current (DC) excitation, low-frequency excitation, RF excitation and microwave excitation methods. Each of the aforementioned methods may be used to generate an atmospheric pressure plasma. “Atmospheric pressure plasma”, also referred to as normal pressure plasma, may be a plasma in which the pressure is approximately equal to the atmospheric pressure. It will be appreciated that the pressure within the chamber 15, even when filled with a desired local atmosphere, will have a pressure similar to the pressure outside the chamber 15. In at least one embodiment, the pressure internal the chamber is around 1 bar to 5 bar, however other pressures greater than 1 bar may be used.

As the plasma module 20 can be used in local atmosphere, a carrier fluid for generating a plasma in the reaction gap 110 may be pumped into the region between the article 1 and the module 20 for a predetermined amount of time such that local atmosphere is evacuated from the region before igniting the carrier fluid such that local atmosphere molecules are not ionised or activated. The region between the article 1 and the module 20 may be referred to as a “local region”. Purging local atmosphere may also be desirable if the system 10 is used within an enclosed chamber such that functional treatment properties can be controlled. For example, purging the chamber 15 may be advantageous as this may allow for the removal of oxygen within the chamber 15 which can react with monomer species or polymerising species.

At least one further fluid may be provided to the plasma region 112 which is carried by the carrier fluid, or injected directly into the plasma region 112. The further fluid will typically be used to treat a substrate 1 or apply a coating. In one embodiment, the further fluid may be a monomer which can be polymerised by the plasma region, and may be used for a plasma enhanced chemical vapour deposition (PECVD). Optionally, the further fluid is provided to the plasma module 20 by at least one further inlet. If a carrier fluid and at least one further fluid are provided to the module 20 the fluids are preferably mixed together in a desired ratio such that a known amount of further fluids can be delivered to a substrate 1 via an outlet.

The monomers may be injected into a plasma chamber 15 as a liquid spray, a vapor or atomised particles and may assist with forming desirable plasma conditions as monomers the monomers may be adapted to stabilise a plasma streamer or plasma corona condition which is formed in the reaction gap 110. Stabilising a plasma condition may mean forming a plasma glow or a stable plasma within the reaction gap 110. It will be appreciated that the voltage and the frequency supplied to the electrodes 100 will also assist with maintaining and/or forming a stable plasma.

In yet a further embodiment, if the article 1 is a substrate, the plasma may be used to treat only a first side of a substrate, while the second side of the substrate may be protected from treatments, or may be separately treated by a different coating or treatment process. This may allow for selective modification of one side of a substrate. Protection of one side of the substrate may be achieved by application of a film or protective layer on the second side of the substrate, or by pressing the second side of the substrate against a surface which will not allow coatings or treatments to be applied to said second side of the substrate.

The power source 30 may comprise more than one power supply unit. The power source 30 can be coupled with a respective module 20, such that the module 20 can be activated, deactivated, altered or otherwise manipulated by a user of the system for a desired treatment process. The power source 30 may also be an RF source to charge RF electrodes, or may be an AC (alternating current) or DC (direct current) power source 30. Electrodes 100 may be formed from with a core with a sheath 104 covering the core 102. The core 102 is formed from a conductive material, such as copper, gold, or stainless steel for example, and the sheath 104 is preferably a dielectric material, such as glass or alumina. The core 102 is preferably a conductive material which can withstand heating to temperatures which are equal to or less than that of the plasma formed in the plasma region. The sheath 104 selected is to be formed from a dielectric material which can encompass or encapsulate the core 102 to reduce arcing and assist with stabilisation of plasma formed in the reaction gap 110. Optionally, a fluid channel 108, such as an air gap or liquid gap, may be provided around the core 102 which can assist with cooling and dielectric properties of the electrode 100. For example, air or inert gas may be used as a cooling fluid which may be passed between the electrode core 102 and the sheath 104. In another embodiment, the electrode 100 is provided with one or more fluid cooling channels or a cooling channel which is used to cool the electrode 100. Optionally, the core 102 may be provided with a fluid channel through which fluids can be passed to cool the electrode 100. Examples of different electrode sheaths 104 are illustrated in FIGS. 5A to 5C.

While electrode sheaths 104 may be a rectangular shape or circular shape, the core 102 may be any predetermined shape which may or may not correspond with the shape of the electrode sheath. For example, an electrode 100 may be a blade type electrode 100 which has a rectangular sheath cross section, however the core may be circular or any other predetermined shape. Fluid conduits may have any predetermined cross section, this may include a regular shape, a sinusoidal shape or a waveform shape cross section. The general shape of the sheath 104 may define the type of electrode 100 regardless of the cross section of the core 102, however there may be advantages in relation to conforming the shape of a core 102 with the shape of the sheath 104.

As the system is functional as an atmospheric plasma system, the chamber 15 does not require a vacuum pressure to operate. Cleaning, functionalisation, and activation of an article 1 can be achieved via different plasma treatment methods and exposure to plasma. In local atmosphere, the functionalisation may impart groups comprising at least one of; oxygen, nitrogen, and hydrogen groups. In another embodiment, the plasma may be used to etch a surface or otherwise modify the surface by removing matter from said surface.

If a surface is activated, reactive groups may be present at the surface which can form superior bonds with particles that interact with the surface. In another embodiment, the nanoparticles may be activated by the plasma, either directly by forming radicals from the hydration water, or by reactions at the surface of the nanoparticle.

The chamber 15 for applying a plasma treatment to an article 1 is preferably purged with an argon atmosphere or similar noble gas atmosphere at room temperature. Optionally, the temperature of the argon, plasma gas, monomer and the solution are controlled to be at around 15° to 50° or more preferably, around 20° C. to 35° C. The mixing chamber 50 or individual gas supplies may also be heated or cooled. Heating a monomer, dispersion or fluid polymer may allow for a higher volume to be carried by the carrier fluid. For example, a substantial increase in Hexamethyldisiloxane (HMDSO) monomer carried by the carrier fluid can be achieved by increasing the temperature of the monomer from 25° C. to 50° C., which can result in thicker coatings be applied within the same time period. It will be appreciated that each monomer used may have a different evaporation temperature or temperature which will allow for a larger volume to be carried by the same volume of carrier fluid. However, it is desired that the temperature of at least one of the monomer, carrier fluid, dispersion and mixing chambers is regulated or controlled to ensure a desired volume and/or concentrations of fluids are delivered into the chamber 15 by the delivery system 40.

In another embodiment, at least one consumable of the system, such as; the carrier gas, monomer, dispersion, plasma gas, nanoparticles, or solution used with the system are temperature controlled individually. Each of these consumables can be temperature controlled to be within the range of −10° C. to +150° C. Other temperature ranges may also be applicable, provided that they are between the freezing temperature of a consumable, and the evaporation temperature of the consumable at the time of being either introduced to a fluid supply line or into the plasma region. It may be advantageous to increase the temperature of some consumables as this may increase the potential for fractionation when entering into a plasma region, and thereby creating a more durable coating or a coating with a desired property. In addition, a carried gas may be adapted to carry a greater volume of at least one of; the monomer, nanoparticles or dispersion, by increasing the temperature of the respective monomer, nanoparticles or dispersion. Alternatively, the carrier gas temperature may also be increased to carry additional monomer, nanoparticles and/or dispersion.

Photoionization (PID) sensors, fluid flow sensors, temperature sensors or other fluid sensors may be used within the fluid delivery system 40 to monitor and control the distribution of fluids. The sensors may also be adapted to determine the concentrations and fluids extracted from the chamber for recycling in the recirculation system 70. Based on the detected concentrations and compositions of the fluids extracted from the chamber 15 and injected into the recirculation system 70, the virgin fluid concentrations and volumes from the fluid supplies may be varied to create a more uniform mixture. It will be appreciated that the recirculated fluids and the virgin fluids may collectively create a desired concentration to be provided to the chamber 15.

In another embodiment, the recirculation system has a storage 95, which may be a tank or other receptacle. More than one storage 95 may be provided which may be used for storing separated fluids. For example, a first storage 95 may be used to store carrier fluids, and a second storage may be used to store monomer or partially polymerised monomer. The storage 95 can be used to temporarily store fluids which have been collected, and may be injected back into the recirculation system 70, or may be removed for further processing or purification.

An atomiser 55 may be used to atomise a monomer and nanoparticle to be carried through the fluid delivery system to the reaction gap 110. The atomiser 50 may be found within the mixing chamber 50. Mixing chamber 50 may be used to mix the nanoparticle and the monomer in predetermined volumes to allow for a desired ratio of monomer to nanoparticle. A syringe or dosing means may be used to inject a predetermined volume of fluid of a monomer and/or a nanoparticle fluid to be mixed within the mixing chamber 50, which can subsequently be atomised. The mixing chamber forming a part of the fluid delivery system 40.

The fluid delivery system 40 may also comprise a plurality gas tubes 114, or conduits, which are adapted to deliver a fluid into the chamber 15. The gas tubes 114 comprise a plurality of gas outlets 116 which allow for a pressurised gas to be distributed into the chamber 15. The gas outlets 116 may deliver a pure substance, such as a desired atmospheric gas, to the chamber 15. The gas outlets may also allow for at least one of a carrier fluid, monomer, monomer mixed with a nanoparticle, nanoparticle mixed with a monomer, and dispersion to be delivered to the chamber 15. The dispersion preferably comprising a monomer which can be polymerised, and nanoparticles therein.

The gas outlets 116 may eject the fluids in such a manner that a stream is formed when the fluids pass into the plasma and towards the article 1. As such, a type of plasma stream may be formed which is unconventional as the plasma gas can be ejected into the chamber atmosphere before being excited to form a plasma at the electrodes 100. It will be appreciated that the above mentioned plasma stream may be similar in appearance to a plasma torch well known in the art, however unlike a plasma torch the plasma stream is formed above an excitation area and forms a low temperature stream of plasma. This is advantageous as the stream can be formed by the pressure of the fluid delivery, and are adapted to move through a free area above the electrodes before entering into the plasma region 112. This provides the benefit of allowing carrier fluids to also enter into the region above the electrodes which can assist with smoothing the plasma generated between the electrodes 100, or creating a more uniform plasma which can extend across multiple sets of electrodes within the chamber 15.

A bias plate 120 may be used to attract ionised matter which can assist with increasing deposition rates or imparting a fluid movement to the ions. The bias plate is preferably disposed below the module 20, such that particles from the module 20 can be drawn down to the article 1. The bias plate 120 may be powered by a bias supply 118, or may be powered by the supply 30.

Preferably, the bias plate 120 is a DC bias plate which is negatively charged. It will be appreciated that the bias plate 120 may be positively charged if desired. Penning traps may be used above and/or below the plasma region, such that ionised matter in the plasma region can be repelled or attracted in specific directions. Preferably, if a Penning trap is used, the polarity of the Penning trap is opposite that of the bias plate if the bias plate is present. A magnetic field may also be used to induce movement of ions within a plasma region and can urge positive and/or negative ions in a desired vector or direction.

Referring to FIGS. 4A and 4B, there are illustrated embodiments of a treatment module 20. The module 20 comprises a housing 22 with a plurality of electrodes 100 mounted therein, and at least one gas outlet 116. The housing 22 being configured to support the electrodes 100 and the gas outlets 116 of the fluid delivery system 40.

The outlets 116 may be in disposed within a diffuser plate (not shown) which assists with distributing a carrier fluid and carried particles or fluids. In the embodiments shown in FIGS. 4A and 4B, gas tubes 114 are disposed with the gas outlets 116. The gas tubes are positioned relatively above the electrodes 100. In a preferred embodiment, the gas outlets 116 are positioned above a reaction gap 110 between the electrodes 100. In this way the gas outlets can focus gases towards the reaction gap 110. The number of gas outlets may be equal to or less than the number of reaction gaps 110, or may be up to 2 more than the number of reaction gaps. However, it will be appreciated that the number of gas tubes within a module may be any desired amount to allow for sufficient delivery of fluids to the electrodes 100 and/or into the chamber 15.

An article 1 is shown relatively below the module 20, and is configured to be passed under the module 20. Passing the article 1 under the module 20 allows for a coating or treatment to be made to the article 1. Rollers 60 or a support 80 may be used to carry or transport the article from a first side to a second side of the module, wherein the article 1′ is a treated article. A plasma region 112 may extend across multiple electrodes 100 as is shown; if the electrodes are energised to maintain a plasma in the reaction gaps. It will be appreciated that the reaction gap is where the first instance of plasma may be formed, and the plasma region may ignite or otherwise excite atmosphere local the electrodes 100 causing a plasma glow. Preferably, the plasma glow is generally even and uniform between multiple sets of electrodes 100 and allows for a much larger area to be treated or coated at the same time that what could be possible with a plasma torch or plasma jet. Further, the plasma region formed by the electrodes is preferably above the article 1 to be coated, such that the plasma is not required to directly interact with the article 1, unless desired. Fluids, such as carrier fluids, atomised monomer, monomer vapour, monomer aerosols and/or nanoparticles may enter into the chamber 15 from outlets 116. The fluids may disperse 124 outwards from the hole, or may be supplied with sufficient pressure to form a column 126 of fluid. The dispersed fluids 124 can be used to spread the fluids across the electrodes 100 and provide regions of varying fluid density. This may assist with the formation of a plasma region 112 which extends across multiple electrodes 100. Alternatively, the column of fluids may be ignited and form a plasma stream. This plasma stream may be used to form spot coatings or more focused coatings in some embodiments. Unlike conventional plasma jets, a plasma stream is a non-thermal plasma in which the plasma fluids may be ejected into the open chamber 15 before reaching the electrodes 100 to ignite or excite the plasma fluids. As such, the fluids injected into the chamber 15 can mix with local fluids within the chamber 15 before reaching the electrodes. This method of forming a plasma may also allow for other gases within the chamber 15 which are not ejected from outlet 114 to be entrained or collected to be carried to the reaction gap 110.

Optionally, the outlets 116 can be varied in size with the insertion of a nozzle or other flow direction or flow restriction device. The outlets 116 may be fitted with a thread or mounting means which can receive a nozzle to change the flow type or dispersion of a fluid entering into the chamber 15. Nozzles may also be used to direct the flow in a desired direction. Nozzles may also be fitted with a solenoid, iris or closure to seal the nozzle if desired. This may be of particular use when using multiple coatings or treatments in the chamber 15 as outlets can be selectively turned on or off.

FIG. 4B comprises a number of circular electrodes, with the reaction gap 110 being the distance centre to centre of a circular electrode 100, as plasma can be formed between opposing polarity electrodes 100. Other electrode cross sections may be utilised depending on the desired plasma to be formed, a desired coating, or desired cooling for electrodes or plasma temperature. A cooling system 45 may be used with the electrodes 100 to cool the temperature of the sheath and/or the core to a desired temperature range. This may assist with reducing damage to articles 1 being treated. The cooling systems may be configured to be in communication with a fluid channel 108 of an electrode 100.

A bias 120 may be provided below the article 1, which can be used to attract the article and/or the fluids from the module 20 towards the article 1. A support 80 may be positioned relatively between the article 1 and the bias 120 as seen in FIG. 4B. In another embodiment, the electrodes 100 may be collectively charged, or otherwise coupled with a high voltage supply, and the bias 120 is grounded such that the plasma is formed between the electrodes 100 and the bias 120. Forming a plasma between the electrodes 100 and the bias 120 may allow for the plasma to extend and engulf or more fully surround the article 1 relative forming a plasma between grounded and high-voltage electrodes 100. It will be appreciated that in another embodiment the bias 120 may be charged with a high voltage supply and the electrodes 100 are grounded. Biases may also be used to impart a visual effect to the plasma region 112. For example, a bias may be used to create a more homogeneous plasma, and/or a more even plasma, which can promote a more desirable coating. The bias may be an electrical bias, such as a DC bias or earthed configuration.

Methods for treating an article 1 may include providing a polymer to an article, having a generally sheet or planar form, in which the polymer has been formed by plasma polymerisation. The article 1 may have at least one fibre or yarn exposed at a surface which can be treated by the system 10. Polymers may be formed by plasma at atmospheric pressure wherein the energy of the plasma is sufficient to cause polymerisation of monomers and subsequent bonding of the polymer to an article 1. The thickness of the polymer coating applied to the article 1 may be dependent on the density of the plasma, the coating time, and the volume of monomer introduced into a plasma region.

In another embodiment, the carrier fluid and atomised matter can be delivered by delivery system 40 to the chamber and dispersed into the chamber through a diffuser plate (not shown). The diffuser plate may be disposed above the electrodes 100, such that the gases can be more evenly distributed to the electrodes 100 at a generally uniform velocity. This may reduce spot coating which can be achieved with the use of a pressurised gas from a gas outlet 116.

In yet another embodiment, the modules 20 may be fitted with a series of lasers which can identify the location of an article relatively below said module 20. Once an article has been identified below the module 20, the electrodes which are directly above the article 1 can be selectively turned on to form a desired plasma. In this way the entire module 20 need not be activated or energised which can be of particular value as resources such as power, plasma gas, monomer, and nanoparticles can be saved as they are not provided to the module 20 in regions which are not relatively above the article 1.

In yet a further embodiment, there is provided a method for depositing nanoparticles on a support comprising the following steps atomising a colloidal solution (or suspension) including nanoparticles and introducing the solution into a plasma region and depositing the nanoparticles and on a surface of said support in an atmospheric plasma.

A nanoparticle may be an aggregate of small molecules, or an assembly of a few hundred to a few thousand atoms, forming a particle, for which the dimensions are in the range of 1 nm to 100 nm. Larger particles may also be carried by the carrier fluid, bonded with the monomer, or otherwise transported with aerosolization or evaporation of the monomer.

A dispersion can be used to apply the desired nanoparticle for plasma deposition coatings. Any desired method of generating a nanoparticle may be used with the process of the present disclosure. While it is preferred that nanoparticles are used to form part of a coating, larger particles, such as microparticles may alternatively be used if they can be transported effectively to the coating region.

In yet a further embodiment, the coating can be formed from a dispersion coating which includes a monomer and/or a nanoparticle which has been hydrolysed. The dispersion may include a silicon-based compound, for example Tetrathoxysilane (TEOS), which may be suitable for providing a repellency functionality to an article 1. Other dispersions may be used depending on the desired end functionality. In yet another embodiment, a dispersion may be used to apply a pigment or nanoparticle to an article 1. Dispersions may be applied to an article 1 before being subjected to a plasma from a module. Optionally, it may be desired that a solvent for a dispersion be removed, evaporated, dried, or extracted from an article before being subjected to a plasma treatment or plasma coating. Removal of solvents may be with the use of heaters, IR treatments, spectral wavelength exposure, exposure to ambient conditions, or evaporation techniques.

If a sol-gel coating is to be applied it may exhibit brittle behaviour, organic compounds or molecules can be incorporated. This may be achieved with the use of organically-modified precursor compounds like glycidoxypropyltrimethoxysilane (GLYMO), methacryloxypropyltrimethoxysilane (MEMO), propyltrimethoxysilane (PTMO), and any other predetermined precursor compound may be used. Any precursor compounds may be included as a portion of the sol-gel to improve the properties of a coating which may be applied to an article 1. Precursors may also impart at least one functional property to the coating applied to an article 1.

In a further embodiment, the system 10 is adapted to transport inorganic salts and metal salts to a plasma region. When salts interact with the plasma region, the salt may be fractionated, and elemental particles may be deposited onto an article. For example, a copper salt may be introduced into a plasma region, with salt being ionised such that separation of copper any other elements of the salt can occur. It is preferred that the salts introduced into the plasma region comprise a reactive non-metal and a metal. Preferably, the reactive non-metal is a gas at room temperature, such as oxygen.

A solution or dispersion with a salt may be injected or provided to the atomiser, and the solution vaporised into an aerosol. Vaporisation can be achieved through any conventional method, and may involve thermal vaporisation methods, sonication methods, and evaporation methods. In some embodiment, sublimation can also be achieved by the atomiser. As monomers and fluids containing nanoparticles may require relatively large droplets to allow for effective carrying of particles, the size of the droplets may be controlled by the use of pressure and temperature of the monomer and/or the nanoparticle. Plasma fluids can be used to carry the droplets to the plasma region 112. Preferably, the droplet sizes are in the range of 0.1 nm to 500 μm.

The combination of vapour and carrier fluid may form an aerosol, wherein the vaporised fluid are the droplets, and the carrier fluid is the gas carrying said droplets. It will be appreciated that while aerosols may transport nanoparticles, some nanoparticles or pigments may need to be bonded or dissolved within a solvent or solution before being converted into an aerosol. In some embodiments, the nanoparticles or pigments in a dispersion may be sprayed with a spraying device onto an article 1, rather than being provided as an aerosol. As such, when these aerosols enter into the plasma region, the bonded or dissolved nanoparticles may be separated and returned to a metal or elemental state which can then be deposited onto the article 1.

Sol-gel processes are a method of forming dispersed inorganic materials in solvents, through the growth of metal-oxo polymers. The chemistry is based on inorganic polymerization reactions. Metal alkoxides [M(OR)_{z}, where M=Si, Sn, Ti, Zr, Al, Mo, V, W, Ce, etc.; or, an alkoxy group OCₙH₂ₙ₊₁] are used as molecular precursors which lead to metal-oxo polymers through hydrolysis and condensation reactions. Reactive hydroxy groups are generated first, and subsequently undergo polycondensation reactions.

In Class I hybrid organic-inorganic materials, organic and inorganic components are linked together through weak bonds (van der Waals, ionic or hydrogen bonds, hydrophobic-hydrophihc balance). These materials will allow for a relatively large diversity of structures formed and final properties being imparted to a coating applied to an article 1.

For example, organic dyes can be embedded in sol-gel matrices. As another example, organic molecules entrapped in an inorganic network may be a hybrid material. Doping of sol-gel matrices, the matrices are still in solution, by organic dyes, inorganic ions or molecules, may result in at least one property such as; fluorescence, photochromic or non-linear optical (NLO) properties.

Organic molecules such as rhodamines, pyranines, coumarins, porphyrins, phthalocyanines and spiropyrans, as NLO dyes can be entrapped in inorganic networks such as silica, aluminosilicate or transition-metal oxide-based gels (ZrO₂, TiO₂). The inorganic matrix selected can be used to change the refractive index, and/or the mechanical properties of the coating formed. An inorganic molecular precursor (alkoxide), dye and catalyst are mixed in a common solvent. The mixture can then be hydrated to begin polycondensation, causing the dye molecules to be uniformly trapped in the polymer. Weak interactions between the dye and the inorganic matrix (hydrogen bonds, van der Waals forces, etc) account for the dispersion of the dye within the structure, and may also contribute to the final properties of the coating, such as photoresponse properties.

Sol-gel inorganic matrices are often porous structures, commonly with pores around 1 nm in size. The pores of the structure may be filled with molecules by immersing the bulk in a solution containing polymerizable organic monomer, and a catalyst. Organic polymerization may then be effected by at least one of a; plasma polymerisation, UV irradiation or by heating processes, or combination thereof. The system 10 may be adapted to treat the article 1 with at least one type of radiation with an appropriate radiation emitter. Organic functional molecules can be also mixed with an organic monomer. Perylene dyes, and also enzymes and porphyrins, can also be incorporated into these materials. These types of materials containing perylene dyes, enzymes and/or porphyrins may have benefits for sensors and composites with longer lasing properties.

Mechanical properties of polymeric blends may be adjusted by incorporating inorganic fillers within the monomer/polymer. The conventional process is to mix together the polymer (or a prepolymer) and the inorganic particles. The high viscosity of this type of mixture may result in agglomeration of particles. The resulting inhomogeneity within the materials decreases the polymer-filler interactions. Optionally, a solvent may be used to reduce homogeneity issues.

These techniques may also be used to generate ceramic fluids which can form a shell type ceramic coating on an article 1. Powders of MgO, Al₂O₃ and SiO₂, may be mixed with a soluble polymer, with the viscosity of the gel being adjustable by changing the concentration of the solute which can assist with atomisation. During polymerisation, the system 10 may distribute the particles from the sol more evenly which may negate the disadvantages of non-homogenous gels. Complex ceramics may be deposited by the system 10, and may be baked, fired or otherwise hardened via a plasma, or by conventional firing methods.

Homogeneity of a sol-gel may also be improved by embedding inorganic particles in polymers. A typical method consists of mixing together the polymer and the metal alkoxide in a suitable solvent (alcohol or THF). A catalyst and water can then be added to the mixture and the polycondensation is performed in situ. The best homogeneity is achieved when the weak interactions developed between both phases are sufficient to force both networks to interpenetrate mutually at the molecular level. These materials have good optical properties which can be changed by adjusting the silica: organic ratio.

Class II materials are hybrid structures in which organic and inorganic components are grafted together through strong covalent or iono-covalent chemical bonds. The molecules used as starting building blocks for Class II hybrids possess at least two distinct functionalities: alkoxy groups (R—OM bonds) which should experience hydrolysis-condensation reactions in the presence of water and lead to an oxo-polymer framework, and metal-to-carbon links which are stable in the hydrolysis reactions. The nature of the stable metal-to-carbon link depends on the nature of the metallic cation. Complexation by polyhydroxylated ligands, organic acids, phydroxyacids, p-diketones and allied derivatives are also used.

A colloid may include a mixture of particles in a fluid. The particles may be homogeneously distributed throughout the fluid, which may be a liquid, or in the case of gels may be a solid. The particles may be soluble or insoluble within the fluid, with the particles either being organic, inorganic, or inorganic salts.

In one embodiment, a colloidal solutions may be used, with the colloid solution taking various forms, such as; a liquid, gel, or slurry. Colloidal solutions are intermediate between suspensions, which are heterogeneous media comprising microscopic particles dispersed in a liquid, and true solutions, in which one or more solutes are in the state of molecular division in the solvent. In the liquid form, colloidal solutions may be referred to as “sols”. The colloidal sol-gel solution may also be referred to as a colloidal sol or a soil.

Sol-gel synthesis in an organic medium from a precursor of nanoparticles, the preparation may comprise the following steps: step (a): hydrolysis-condensation of organometallic precursors or of metal salts in organic or hydroalcoholic medium; step (b): nucleation of the stabilised and dispersed nanoparticles in an organic or hydroalcoholic medium by ripening, growth; step (c): optionally formation of an organic-inorganic hybrid sol by dispersion of the particles within an organic polymer or oligomer and/or by functionalisation of the surface of the particles by any type of reactive organic functions.

Sol-gel synthesis in an organic medium with different precursors (metalloid salts, metal salts, metal alkoxides), may be used as the sol-gel comprising nanoparticles or pigments. As such, the nanoparticles can be directly stabilised in the solvent used during the synthesis or peptized later if they are synthesized by precipitation. Either method may still yield a suspension.

Whatever the route of preparation chosen, the nanoparticle precursor may be selected from the following group; a metalloid salt, a metal salt, a metal alkoxide, or a mixture of these. For example, the metal or metalloid of the salt or of the alkoxide precursor of nanoparticles can be chosen for example from the group comprising silicon, titanium, zirconium, hafnium, aluminum, tantalum, niobium, cerium, nickel, iron, zinc, chromium, magnesium, cobalt, vanadium, barium, strontium, tin, scandium, indium, lead, yttrium, tungsten, manganese, gold, silver, platinum, palladium, nickel, copper, cobalt, ruthenium, rhodium, europium and other rare earths, or a metal alkoxide of these metals.

In another example, an aqueous solution of a metal salt may be reduced to a colloidal metal nanoparticle. The reduction reaction may occur within a plasma region 112 at the time of excitation of the salt within the solution. This can allow for a polymer to be formed, while also allowing for reduction of a salt into at least a partially elemental form. The elemental metal may then be embedded, bonded or otherwise fixed with the plasma formed polymer. Unlike conventional plasma treatment systems, an entire coating may form desired crosslinking throughout the thickness of the polymer as nearly all monomers, or greater than 60% of the monomer, is fractionated as it passes through the plasma region. More preferably, at least 80% of the monomer is fractionated, or more than 95% of the monomer is fractionated, or more than 97% of the monomer is fractionated, or more than 98% of the monomer is fractionated, or more than 99% of the monomer is fractionated. Conventional methods in contrast may only activate or excite the uppermost portion of a pre-applied coating which can cause only a partial polymerisation, or a partial crosslinking of the coating. As such, these coatings may be weaker or less durable compared to coatings which can be achieved with the present system 10.

Fractionation percentages will be related to the overall efficiencies of the system, and may also be related to the plasma density and the volume of monomer injected into the chamber 15 to be polymerised.

In another embodiment, the sol can be prepared for example by synthesis of a solution of metallic nanoparticles from a precursor of metallic nanoparticles using an organic or inorganic reducing agent in solution, for example by a chosen process in the group comprising: a reduction of metal salts in an emulsion medium; and a chemical reduction of organometallic or metallic precursors or metallic oxides.

Regardless of the process, the reducing agent may be selected from at least one of the following group comprising; polyols, hydrazine and its derivatives, quinone and its derivatives, hydrides, alkali metals, cysteine and its derivatives, ascorbate and its derivatives. The precursor of metallic nanoparticles can be chosen from any of the above-mentioned metal salts or metal or metalloid salt.

In yet a further embodiment, the sol can be prepared by preparing a mixture of nanoparticles dispersed in a solvent. However, regardless of the method of obtaining the sol, more than one sol may be used, with one or more methods being used to derive each of the respective sols.

In another embodiment, the sol used in the process may comprise nanoparticles of a metal oxide, for example, at least one metal oxide from the following group; SiO₂, ZrO₂, TiO₂, Ta₂O₅, HfO₂, ThO₂, SnO₂, VO₂, In₂O₃, CeO₂, ZnO, Nb₂O_{5,}V₂O₅, Al₂O₃, Sc₂O₃, Ce₂O₃, NiO, MgO, Y₂O₃, WO₃, BaTiO₃, Fe₂O₃, Fe₃O₄, Sr₂O₃, TiO_{3,}Cr₂O₃, Mn₂O₃, Mn₃O₄, Cr₃O₄, MnO₂, RuO₂, or a combination of these oxides for example by doping the particles or by mixing the particles. The above oxides are exemplary only, and other metal oxides may also be used within the sol.

The size of the nanoparticles of the sol obtained is perfectly controlled by its synthesis conditions, in particular by the nature of the; precursors, solvents, pH, temperature, or any other predetermined condition. For example, in the applications mentioned herein, the nanoparticles preferably have a size of 1 to 100 nm, this in particular in order to be able to produce thin layers or coatings, for example of thickness ranging from 0.1 to 50 μm.

Besides nanoparticles, the sol also includes a carrier liquid, which comes from its manufacturing process, called growth medium. This carrier liquid is an organic or inorganic solvent such as those described in the aforementioned documents. It may for example be a liquid chosen from water, alcohols, ethers, ketones, aromatics, alkanes, halogens and any mixture of these. The pH of this carrier liquid depends on the manufacturing process of the sol and its chemical nature.

In the sols obtained, the nanoparticles are dispersed and stabilised in their growth medium, and this stabilisation and/or dispersion can be promoted by the process of preparation of the sol and by the chemistry used. As the sols can also comprise organic molecules, the organic molecules may be used for stabilising nanoparticles in the sol and/or molecules which can assist with functionalisation of the nanoparticles.

Organic compounds may be added to the nanoparticles in order to give them a predetermined property. For example, the stabilisation of these nanoparticles in a liquid medium by steric effect leads to materials called hybrid organic-inorganic materials of class I. The interactions which govern the stabilisation of these particles are weak of an electrostatic nature of hydrogen bond or Van Der Waals.

Nanoparticles can be functionalised with an organic compound either during the synthesis by the introduction of suitable organomineral precursors, or by grafting on the surface of the colloids. Examples have been given above. These materials are then called class II organic-inorganic materials since the interactions present between the organic component and the mineral particle are strong, of covalent or ionocovalent nature.

The properties of the hybrid materials depend not only on the chemical nature of the organic and inorganic components used to constitute the sol, but also on the synergy which may appear between these two chemistries.

The temperature of the sol during its injection can range, for example, from ambient temperature (20° C.) to a temperature below its boiling point. Advantageously, it is possible to control and modify the temperature of the sol for its injection, for example to be from 0° C. to 60° C., or any other predetermined temperature range. The sol may then have a different surface tension, depending on the temperature imposed, resulting in a more or less rapid fragmentation mechanism and effective when it enters the plasma. The temperature can therefore have an effect on the quality of the coating obtained. This is of particular advantage when using atmospheric plasma as the general temperatures achievable are lower than that of thermal plasma jets.

The injected sol, for example in the form of drops, enters the atmospheric plasma region 112, where it is exploded into a multitude of droplets under the effect of the shearing forces of the plasma. The size of these droplets can be adjusted to impart a desired microstructure for the deposited coating and nanoparticle dispersion. Preferably, the average size of the droplets may be in the range of 0.1 μm to 10 μm. Further, the microstructures may also be altered by the type of plasma in the plasma region, the frequency, power, plasma density and the temperature of the droplets.

An atomiser is used to convert the sol into droplets and disperse the drops into a carrier fluid. The velocity of the carrier fluid can direct the vaporised sol into a plasma region 112 to be polymerised. The temperature of the plasma between the electrodes may be of a generally uniform temperature such that fractionation occurs more evenly throughout the plasma region 112. During fractionation, nanoparticles may be adapted to agglomerate before being dispersed. Particles exiting the plasma region 112 are preferably dispersed evenly onto the article 1 below.

The substrate to be coated is, for obvious reasons, preferably positioned with respect to the plasma jet so that the projection of the nanoparticles is directed onto the surface to be coated. Different tests make it very easy to find an optimal position. The positioning is adjusted for each application, according to the projection conditions selected and the microstructure of the desired deposit.

The rate of growth of deposits, high for a process for manufacturing finely structured layers, depends essentially on the mass percentage of material in the liquid and the liquid flow rate. The method for use with the system may provide for a deposition rate of the coating of nanoparticles from 0.01 μm/min to 100 μm/min. The deposition rate may be altered by modifying the volume of monomer or sol-gel which is provided, and the configuration of the electrodes and the power supplied thereto.

The thin layers or coatings which can be deposited onto an article 1 with a thickness in the range of 0.1 μm to 250 μm (per minute of exposure). The nanoparticle grains within the coating may be of smaller size than when in the sol-gel, or of the order of a several nanometres to approximately a micron. The nanoparticles may optionally be at least one of; porous, dense, pure, and homogeneous. Preferably, the system allows for preservation of at least one of the properties of the starting sol within the coating, and may be used to control at least one of the following properties: porosity, density, homogeneity, exotic stoichiometry (mixed sols and other mixtures), nanometric structure (size and crystalline phases), grain size, thickness of the homogeneous deposit on object with complex shape, possibility of deposit on all types of substrates, whatever their nature and roughness.

The process can be repeated one or more times on the same article 1 or substrate 200, with different solgels or dispersions. The sols may have a different composition and/or concentration and/or particle size, such that successive layers of different coatings can be applied or else deposits with composition gradients. These deposits of successive layers are useful for example in applications such as layers with electrical properties (electrode and electrolyte), layers with optical properties (low and high refractive index), layers with thermal property (conductive and insulating), diffusion barrier layers and/or layers with controlled porosity.

The spraying process may be industrially applied applicable as its specificity and its innovative character reside in particular in the injection system which can be adapted to all thermal spraying machines already present in the industry; in the nature of the sol-gel solution; and in the choice of the plasma conditions for obtaining a nanostructured coating having the properties of the projected particles.

In yet another embodiment, there may be provided a system 10 for coating a surface of a substrate 200. The system 10 comprising: a non-thermal plasma, a gas outlet capable of producing a plasma stream, a plasma gas reservoir, a sol reservoir of nanoparticles, a means for moving the substrate 200 relative to the plasma, and an atomiser for vaporising the sol reservoir such that the sol vapour can be carried by a carrier fluid.

Advantageously, the system 10 comprises several reservoirs respectively containing several sols loaded with nanoparticles, the sols being different from each other by their respective composition and/or diameter and/or concentration. The system 10 may further comprise a cleaning reservoir containing a solution or solvent for flush, sterilise or cleaning the fluid delivery system.

The flow rate and the volume of carrier fluid and sol depends on at least one of; the pressure within the mixing chamber, the pump used, the outlet 116 and the size of the droplets of the aerosol. The aerosol exits the gas tube via outlets 116 with a pressure which may be in the range of 1 bar to 5 bar. The internal pressure of the camber 15 is preferably in equilibrium. The outlet 116 may be of any shape allowing the aerosol to be introduced into the chamber 15. For example, the outlet 116 may be a circle, a slit, a square, a rectangle, an ovoid, or any other predetermined shape. Optionally, the wall thickness of the gas tube may allow for an angled outlet conduit to be formed, a spiral conduit, or any other predetermined structure which may impart a fluid motion to the aerosol, or assist with dispersion of the aerosol into the chamber 15.

The orientation of the outlets 116 relative to the plane of the electrodes 100 can vary from 20 to 160, with 90 degrees being perpendicular to the plasma region 112. It will be appreciated that the plasma region 112 may extend to the full area, or near to the full area between the electrodes and the support 80 above the bias 120. The plasma region 112 formation will be governed by the power supplied to the electrodes 100 and/or bias 120 and the spacing between adjacent electrodes and the spacing from the electrodes 100 to the bias 120. The outlets 116 may also be displaced relative to the plasma region 112. As such, the injection of the vaporised or aerosolised sol and carrier fluid into the plasma region 112 can be directed. This orientation makes it possible to optimise the injection of the sol, and therefore the formation of the coating projected onto the surface of the substrate.

Preferably, the fluid reservoirs are thermostatically controlled so as to control and modify the temperature of the sol when entering into the mixing chamber. This temperature control and this modification can be carried out to assist with vaporisation and also improve the surface tension of the sol which may assist with vaporisation, aerosolization, and/or polymerisation.

In yet a further embodiment, a direct injection system may be used to provide an aerosol into the chamber 15. Using this system 10 a stable suspension of nanoparticles can be directly injected into the chamber rather than being vaporised in the mixing chamber and carried to the chamber 15 by the carrier gas.

The system 10 may allow for coatings to be applied to an article 1 where the size of the nanoparticle deposited is the same as that of the sol, particle distribution is even in the coating, the conservation of the state of homogeneity, and control of the porosity of the deposited coating. The system is preferably adapted to allow for deposition of greater than 70% by weight of the vaporised fluid into the chamber 15. The system also provides for a relatively low temperature coating to be applied to an article 1, which is advantageous for both thermally sensitive sols and also articles 1 which cannot be subjected to relatively high temperatures, or prolonged high temperatures. A relatively high temperature may be 100° C. or above.

Coatings from the system 10 can be applied and deposited successfully onto articles 1 with carrying surface roughnesses, while also maintaining mechanically resistant and adherent coatings.

The system 10 may have utility in more than one technical fields where it is necessary to obtain a nanostructured coating. The system 10 may be used to provide a coating which is relatively homogenous in relation to nanoparticle dispersion, coating thickness and particle size (particularly with respect to agglomerated particles). Coatings which comprise metals and/or oxides may be used to make articles 1 resistant to corrosion.

The deposition of abrasion resistant composite coatings. The deposition of coatings resistant to high temperature, such as the deposition of refractory materials and composite coatings. The deposition of coatings which are involved in interactions of surfaces in relative motion (tribology), such as abrasion resistant composite coatings and/or lubricants.

The deposit of coatings which are involved in the conversion and storage of energy, such as coatings which are involved in the photothermal conversion of solar energy. For these types of coatings a colloidal sol coatings may have the form of stacks of active materials, for example for electrodes and electrolytes, for example for solid oxide fuel cells, electrochemical generators, for example lead batteries, Li-ion batteries, and supercapacitors.

In another embodiment, the atmospheric plasma is a cold atmospheric plasma. A cold plasma may be a partly or totally ionised gas with a temperature in the range of −20° C. to 180° C. Dispersions of pigments or nanoparticles may be provided to a plasma region 112 directly or may be provided to an article 1 before being treated by a module 20.

The nanoparticles which may be used to form part of a coating may be nanoparticles of a metal, metal oxide, metal alloy or a mixture thereof. Optionally, the nanoparticles are nanoparticles of at least one transition metal, of its corresponding oxide, of an alloy of transition metals or of a mixture thereof.

The nanoparticles can be selected from the group formed by silver, aluminium, magnesium, strontium, titanium, zirconium, chromium, tungsten, iron, cobalt, nickel, platinum, copper, gold, zinc, tin, lead, oxides thereof, or any other predetermine metal or alloy. Other suitable nanoparticles may include at least one of the following group; titanium dioxide, copper oxide, zirconium dioxide, and aluminium oxide. In yet another embodiment, the system may be used are selected from the group formed by a gold/platinum (AuPt), platinum/ruthenium (PtRu), cadmium/sulfur (CdS), and lead/sulfur (PbS) alloy.

Some nanoparticles may be oligodynamic in nature and may be produced from precursors selected from the group of; Triphenyltin hydroxide, triphenyltin acetate, thallium sulfate, silver sulfadiazine, silver nitrate, thiomethyl triphenyllead, copper sulfate, barium polysulfide and other precursors or nanoparticles mentioned previously. It will be appreciated that any nanoparticles produced or used which are to contact the skin or tissue of a human are desirably nontoxic, and desirably non-nephrotoxic.

The plasma fluid for forming a plasma is selected from the group of; argon, helium, nitrogen, hydrogen, oxygen, carbon dioxide, air or a mixture thereof. It will be appreciated that the plasma gas is preferably a noble gas, which goes not interact with chemistry of the monomer or nanoparticles injected or provided to the plasma region.

The method for depositing nanoparticles according to at least one embodiment the invention involves a dispersion comprising nanoparticles or suspension with nanoparticles being passed through a plasma region and deposited onto the surface of an article 1. It will be appreciated that the nanoparticles may be a pigment which is of a size in the nanometre to micrometre range.

The systems has a number of benefits, such as removing traditional wet coating processing methods, which are generally resource intensive. Further, depositing a nanoparticle and/or a plasma polymerised monomer onto the surface of the substrate also allows for a greater control of the coating and reduced the potential for contaminants to be included within the coating. In addition, utilising the system can also be used to coat substances with a low surface energy which may be otherwise difficult or impossible to coat. For example, a low surface energy may be associated with a hydrophobic or near hydrophobic material, and it may be desirable to also coat materials with an even lower surface energy. Coating can be achieved by activation of the surface of the low surface energy surface, which may be a coating or a substrate surface, to therefore increase adhesion of new coatings or new particles. Further, application of thinner coatings may be achieved by being able to coat a low energy surface more easily. This is due to the fact that coatings are not needed to bond encapsulate or bond with other portions of the coating to achieve a durable end coating. As such, thinner coatings, which can be localised to one side or need not encapsulate yarns or fibres of the substrate, can be achieved by the system 10. Further, using the system 10, particles may be deposited onto a surface with low surface energy and may bond more reality than conventional coating methods. This is of particular importance in relation to polyamides which are generally repellent to fluids, and are also commonly used within personal protective equipment fields, such as for gowns and masks.

In view of the above, the system 10 may be utilised to provide thinner coatings of antibacterial or antipathogen coatings which may also be applied to surfaces that are traditionally difficult or impossible to coat. Further, the thickness of the coating can be in the range of nanometres rather than micrometres or greater. The system 10 may also be adapted to coat only one surface of a porous substrate, without covering or protecting a second side of said porous substrate, which would be otherwise impossible using conventional treatment methods. Such coating techniques may also have utility with regard to face masks, medical gowns, personal protective equipment and other generally disposable medical items.

An optional surface activation step may be used which exposes an article 1 to a plasma. This can increase the adhesion of a subsequent particle coming into contact with the article 1, such as the nanoparticle and a polymeric coating. Preliminary plasma treatments may also allow for the control of the surface properties of the interface between the coating (including nanoparticles) and the article 1.

A colloidal solution of nanoparticles may be prepared by any predetermined method known in the art and may be selectively injected into a mixing chamber which can then be mixed with a monomer and/or a carrier fluid.

In yet another embodiment, clusters of nanoparticles can be deposited onto the surface of the article 1 and are fixed to the article 1 surface, or are embedded in a polymeric coating which is bonded or fixed to the article 1. The nanoparticles deposited may be organised in packets of clusters of nanoparticles which generally have the same particle diameter as those of the initial colloidal suspension.

Nanoparticles or pigments may receive a charge when being introduced into a plasma region which may assist with cluster formation. The advantage of clusters is that they may allow for a more concentrated release locations on an article 1. A release location may be a location which can release or diffuse a pathogen inhibiting effect. For example, a release location may be adapted to diffuse or release ions which may disrupt a cell wall or other pathogen structure. Conversely, the nanoparticles or pigments applied to an article may not be charged such that there are little to no attraction to avoid agglomeration or clustering of the nanoparticles or pigments for a more uniform dispersion on the article 1.

The system 10 may be adapted to inject a sol-gel or dispersion comprising nanoparticles or pigments into a plasma region. The sol-gel or dispersion may be atomised, or evaporated before being injected into the plasma region. If the sol-gel or dispersion is to be applied to an article 1 before being exposed to a treatment process from a module, it may be advantageous to remove all portions of the sol-gel and/or dispersion which are liquid and leave only the nanoparticle or pigment on the article, such that the nanoparticle or pigment can be fixed in place with a plasma coating.

In yet another embodiment, the nanoparticles may be desired to breakdown, or otherwise reduce in structure or size when passing through a plasma region, such that the nanoparticles can be dispersed throughout the coating being applied to an article 1. It will also be appreciated that the general size of a nanoparticle may remain unaltered when passing through the plasma. Using this method to apply a nanoparticle may make it possible to avoid the use of stabilising additives such as dispersants or surfactants, which is common in the art when applying nanoparticles.

Preferably, the coatings applied to an article are homogeneous in nature, in which nanoparticles are evenly dispersed across the treated surface. Optionally, the system 10 may be adapted to actuate the supply of nanoparticles into the fluids supplied to a plasma region, such that predetermined regions of an article 1 are coated with a nanoparticle and other portions are not.

It is preferred that the limited exposure to the plasma does not permanently alter the properties of some nanoparticles, and thereby allows the nanoparticles to function or behave in an expected manner within the coating. Alternatively, the nanoparticle may be permanently changed by exposure to plasma, and may be considered to be “activated” after exposure. This may allow for a chemical reaction or a physical reaction to occur at either the surface of the article 1, or within the polymeric portion of the coating. For example, some nanoparticles may be applied with a charge or may form an oxide or compound with the coating or a plasma fluid.

If the article 1 has been used in advance of plasma treatment, then the surface of the article 1 which is desired to be coated may optionally be cleaned to remove organic and/or inorganic contaminants which could prevent a successful deposition or coating on the surface. Further, cleaning the article may also to improve the adhesion of the coating. Cleaning an article 1 may be conducted by physical, chemical, radiation or mechanical cleaning methods. In yet another embodiment, cleaning of article may occur when the article 1 is subjected to a plasma.

More than one type of nanoparticle may be provided within the sol-gel or dispersion, with each nanoparticle being adapted for a predetermined function. For example, a first nanoparticle may be a biocidal nanoparticle, and a second nanoparticle may be a reactive nanoparticle which reacts at the surface of the article 1.

In one example the nanoparticles preferably have a size of 1 to 100 nm, this in particular in order to be able to produce thin layers or coatings, for example of thickness ranging from 0.1 μm to 50 μm. In another example, the pigments mentioned herein may have a size in the range of 1 nm to 250 micron.

The sol-gel may be mixed with a carrier fluid, which may be a mixture of monomer and plasma gas. The mixture may then be injected into a plasma region, or dispersed into a plasma region. It is preferred that the monomer and/or the sol-gel are atomised to assist with transporting the monomer and/or sol-gel (or nanoparticles therein) to a plasma region. Further, atomisation also provides for a larger portion of the mixture supplied to the plasma region to be successfully ionised within the plasma region, or otherwise provides for a more effective polymerisation of the monomer.

Preferably, all fluids provided to an article or to the system are temperature regulated such that variance in external conditions do not impact the volume supplied and the respective concentration of pigments, monomer or nanoparticles.

The kinetic and thermal energies of the plasma are used to disperse the polymerised monomer and the nanoparticles onto the article 1. A coating with a plurality of nanostructured deposits can be formed on the surface of an article 1, with the polymeric coating polymerising and embedding and/or encapsulating the evenly distributed nanoparticles within the coating. Using this method, traditional wet coating processes can be avoided which is advantageous as these methods cannot provide a reliable distribution of nanoparticles relative to the present invention. Further, as traditional coating methods can be avoided, there is a greater assurity that a desired volume of nanoparticles are fixed to the article 1.

While there are a number of advantages of the present method of applying nanoparticles to an article 1, the method is of particular advantage with regards to articles which cannot be subjected to wet treatment methods. For example, textiles, fabrics and other substrates may be suitably treated with conventional wet coating methods, and via the application methods disclosed herein, however the application of a coating to an electronic device cannot be achieved using said traditional methods. Therefore, the present method of applying a nanoparticle to an article may have particular advantage with respect to electronics.

In one embodiment, the monomer is the suspension or solvent for the nanoparticle, such that the monomer and the nanoparticle are referred to collectively as a “sol-gel”. Other types of sol-gels may be used with the system 10, as discussed herein. Optionally, a sol-gel may comprise a portion of a final coating composition and be mixed with one or more other sol-gels, vaporised fluids, or evaporated fluids to form the coating.

The process of the invention can be implemented several times on the same substrate surface, with sol-gels of differing composition, concentration and/or particle size. Applying more than one layer to an article 1 can be advantageously used to provide for coatings which offer different functional properties, or may assist this improving abrasion resistance if a lamination effect is desired.

In yet another embodiment, the system may be adapted to apply a conductive coating wherein the coating comprises nanoparticles which have been applied by a plasma treatment process.

Application of the coating may be done via a stencil and spot coating methods. Spot coating may be a focused coating method which can leave a “spot” or localised coating or deposit applied to an article 1. The spot coating method may optionally utilise a stencil or other covering to more accurately apply a coating to an article 1. As the article 1 is displaced relative to the module 20, the stencil will prohibit or block parts of the article from being coated, which can leave an impression of the stencil on the article 1. This may be of particular advantage if depositing an aesthetic coating, such as a photoluminescent coating, reflective coating, conductive coating, or any other coating which may be observed under predetermined conditions. Optionally, a focused spot coating may be achieved such that the article 1 does not move relative to the module 20 when the stencil is applied.

The first treatment may comprise a nanoparticle which is then covered by a coating which is non-conductive. This may allow for use of the conductive coating in clothing and other electronic textiles. Further, flexible membranes may also be formed using the methods described herein.

The spacing of the electrodes 100 may be any desired spacing. The electrodes 100 may be constructed with parallel, grounded, hollow circular or oval tubes having a desired diameter. It is preferred that the electrodes 100 have a uniform spacing such that corona discharges are less likely to occur during use which can damage electrodes 100. Spacings may have a maximum distance such that a desired plasma density can be formed. Further, it is preferred that the electrodes 100 comprise a uniform diameter or cross-sectional area.

Turning to FIGS. 5A to 5C there are shown several embodiments of electrodes which may be mounted in a treatment head. FIG. 5A shows a circular electrode with a circular core. The core 102 of the electrode 100 is received in a channel 106 which is sized to correspond to the diameter of the core 102. This may provide for a relatively tight fit between the channel 106 and the core 102, such that the core 102 is retained within the channel with minimal axial movement when in use.

It will be appreciated that the core 102 and the sheath 104 may be concentric shapes, with the outer shape of the sheath 104 being sized to generally correspond with the shape of the core 102. In another embodiment, the core 106 is formed with a fluid channel 108 which can allow fluids to be passed through to cool the electrode 100 when in use. Fluids used to cool the core may include; water, inert gases, oxygen, nitrogen, and coolant liquids, for example. The fluid may also be used to impart a motion to the plasma generated, which may be altered by increase or decrease of the flow rate of the cooling fluid through the channel 106.

FIG. 5B illustrates a rectangular electrode sheath 104 with a rectangular core 102. The electrode 100 is a “blade” electrode as the length of the electrode exceeds the width of the electrode. Optionally, the electrode 100 may have one or more fluid channels 108 which allows for the passage of a coolant. Coolants may include inert gases, water or any other predetermined fluid.

FIG. 5C illustrates yet another embodiment of an electrode 100 which can be used with the system. The electrode 100 comprises a plurality of cooling channels 108. Each cooling channel 108 may be sized the same as the core channel 106 formed for the electrode core 102. Optionally, each channel 106, 108 may be fitted with a respective core 102 which can be supplied power to excite a plasma gas. It will be appreciated that pairs of electrodes 100 will be required to form a region in which plasma can be formed. Each of the channels are preferably uniformly spaced in the electrode sheath 104 with the channels at the outer ends having a thickness to the outer surface which is equivalent to the spacing between the channels. Other shapes and configurations may be used depending on the geometry of the cores 102 and the desired plasma to be formed.

The shape of the outer surface of the electrode is a “stadium” shape, or more simply a rectangle with rounded ends. Having rounded ends may reduce the potential for monomer and/or particles to build-up on the electrode 100 and may also reduce the potential adverse fluid flows from the system. Preferably, the electrodes 100 are shaped to promote a fluid flow toward the article 1 to be coated.

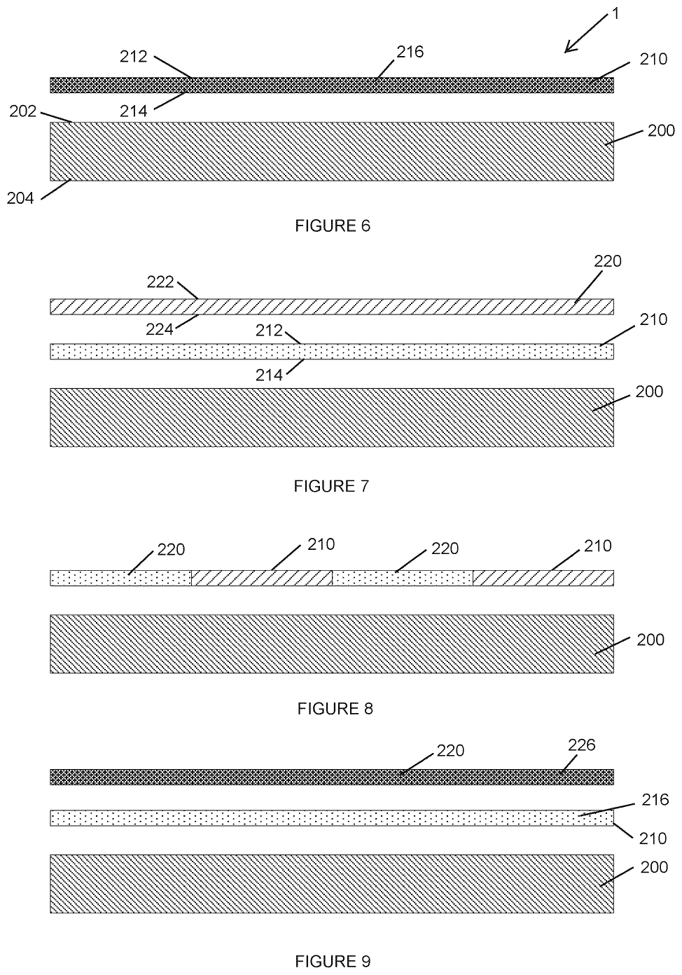

Referring to FIG. 6, there is shown a substrate 200 with a first coating 210, which is a pathogen inhibiting layer, conferring antimicrobial properties or pathogen inhibiting properties. The first coating 210 may comprise a polymer with a dispersion of nanoparticles selected from one or more of the following group; titanium, aluminium, zinc, gold, silver, cesium, copper, sulfates of calcium, strontium, barium, zinc sulfide, copper sulfide, titanium dioxide and barium zeolites, brass, mica, talc, kaolin, mullite or silica, oxides thereof and any other predetermined inorganic or organic nanoparticle. In addition, lead or mercury compounds may also have some use depending on the application. The thickness of the first coating 210 on the substrate may be in the range of 5 nm to 200 nm, although thicker coatings can be applied if desired depending on the speed of the substrate and the deposition rate of the module 20. Nanoparticles may be a near pure metal (greater than 95% purity, or more preferably greater than 99% purity), a metal alloy, or sulfides or sulfates of any other aforementioned metals.

The coating 210 may be a polymeric coating which is formed by a plasma polymerisation process and can be used to embed to fix the nanoparticles to the article. The coating 210 will have an upper surface 212 and a lower surface 214 which will be in contact with the article 1. The upper surface of the first coating 210 may be in direct contact with a second coating 220 if deposited thereon. Similarly, the second coating 220 also has an upper surface 222 and a lower surface 224. The article 1 comprises an upper surface 202 and a lower surface 204, with the upper surface being coated with the first coating 210. It will be appreciated that more than one surface of the article 1 may be coated with the first and/or second coatings.

The surface in which a coating touches, bonds or reacts with an article 1 is referred to as an interface. Similarly, the surfaces between the first coating and the second coating may also be referred to as the interface between coatings. As any number of coatings may be provided to the article 1, each abutting coatings may have respective interfaces.

The polymer of the coating may be a functional coating, or may be used to merely fix the nanoparticles to the article 1. Optionally, the article 1 comprises one or more species of nanoparticles thereon, or therein, before being plasma treated. While the thicknesses of the first coating and the second coatings are generally the same, the first and second coatings can have any predetermined respective thicknesses. Further, while the coatings 210, 220 are shown as generally linear, the coatings may be etched, undulated, or textured in any desired way. Optionally, a mould, heat process or further plasma process may be used to texture the surface of one or more coatings. Texturing the surfaces of the coatings may improve at least one of; adherence of a further coating to be applied, gripability, handfeel, softness, surface retention or any other predetermined characteristic of the coating.

Referring to FIG. 7, there is shown a further embodiment of an article 1. The article is a substrate 200 which includes a first layer 210 with nanoparticles and a second layer 220 which is a functional coating layer. Ions of the nanoparticles of the first layer may be adapted to release, transition or diffuse through the second layer, such that the surface of the second layer can be imparted with a pathogen inhibiting effect. The second layer 220 may be a protective coating which can be used to slow the diffusion of ions from the first layer 210, or may be a functional layer which provides for at least one functionalisation selected from the following group; flame retardant, UV absorbing, self-cleaning, hydrophobic, hydrophilic, and/or antibacterial. Other functionalisations may also be applied as is known in the art.

Turning to FIG. 8, there is illustrated a substrate 200 a first coating with a nanoparticle and a second coating without a nanoparticle. The first coating 210 and the second coating 220 may be applied with the use of a stencil which covers a portion of the article 1, in this instance a substrate 200, such that a desired coating can be applied, and the stencil may be removed and replaced with a second stencil, which may be the negative of the first stencil such that any gaps or spacing between the first coating can be filled with the second coating. In this way the first and second coatings may be applied within substantially the same plane. Alternatively, the second stencil is not required and a second coating 220 is applied over the first coating 210 and the substrate 200. This may induce an undulation or surface texture on the upper surface of the second coating. The nanoparticles 216 of the first coating 210 may be a conductive nanoparticle, or may form a conductive coating with the polymer surrounding it, which can allow for the passage of current. Such coatings may be used for flexible circuits, e-clothing, or other electrical conductive purposes. Optionally, the second coating 216 may also comprise nanoparticles 226. This type of coating may be advantageous as the article 1 may be treated with a variable coating which can selectively provide a functionality.

FIG. 9 illustrates a further embodiment of an article 1 which is a substrate 200 with a first and second coating 210, 220. The first coating 210 being applied directly to the substrate 200, and the second coating 220 being applied to the upper surface of the first coating. Each of the first coating 210 and the second coating 220 comprising nanoparticles 216, 226, which may be the same or different nanoparticles. If the nanoparticles 216, 226 are the same, the polymer being used to affix the nanoparticles to the surface of the article 1 may be different with an optional respective functional property. Forming a multi-layered coating may also be used to form laminations which can act as barriers for ion diffusion from nanoparticles, or may be used to divert, slow or inhibit the rate of ions or the nanoparticle reacting or diffusing between coatings. The lower surface of the second layer may be chemically or mechanically bonded to the upper surface of the first coating.

Optionally, a primer or intermediate layer may be provided between one or more layers which can assist with bonding a plasma treatment or coating formed by a plasma. Primers may also be used to affect a chemical reaction at the upper surface of the article 1, such that a desired property can be achieved. For example, the primer may be used to improve the bond between the article and the first coating 1. In another example, a chemical reaction between the primer and the coating may increase the stiffness or decrease the stiffness of the article with the coating. Other properties may be desired and applied with the use of other primers or local atmospheric conditions within the chamber 15.

In yet another embodiment, a coating applied to the article 1 can be etched to reveal a large number of nanoparticles which have been deposited onto the substrate. In yet a further embodiment, the article 1 may be etched before receiving a coating, or during the coating process. Etching may assist with depositing nanoparticles, and may provide for recesses in which nanoparticles or coatings may be deposited in relatively larger thicknesses.

Other physical or chemical vapour deposition processes may be applied to the article 1 in advance of treating the article 1 with the plasma system 10. As such, the article may receive multiple coatings, in which the coatings are applied in discrete areas of the article 1, or are layered or otherwise laminated onto the article 1.

In at least one embodiment, it is preferred that at least one coating is provided with a pathogen inhibiting nanoparticle such that the coating can be used to destroy, inhibit, kill or otherwise deactivate a pathogen which comes into contact with the surface of the coating.

In a preferred embodiment the pathogen inhibiting coating includes copper and/or silver as a pathogen inhibiting material. Silver and copper have been observed to have an effect on bacteria with the silver ions and copper ions being used to denature proteins in target bacteria by binding to reactive groups. This binding can result in precipitation and deactivation of a pathogen. Silver has also been shown to inhibit enzymes and metabolic processes. Cationic species are electrostatically attracted to the negatively charged bacterial cell walls. Cationic antimicrobial peptides have been shown to have an inhibitory effect on target bacterial regulatory mechanisms.

The present invention therefore also provides a composition comprising nanoparticles as described above for use as an antipathogen agent. The nanoparticles may suitably be formulated in an appropriate carrier, coating or solvent such as water, methanol, ethanol, acetone, water soluble polymer adhesives, such as polyvinyl acetate (PVA), epoxy resin, polyesters etc, as well as coupling agents, antistatic agents. Solutions of biological materials may also be used such as phosphate buffered saline (PBS), or simulated biological fluid (SBF).

Application of the agent may be achieved by any one of the following processes; spray coating, electro-spray coating, dipping, plasma coating, and plasma polymerisation. Other processes may be used to achieve a suitable coating.

Articles which are protective clothing may be prepared from any suitable fibre or fabric, such as natural or artificial fibres. Natural fibres include cotton, wool, cellulose (including paper materials), silk, hair, jute, hemp, sisal, flex, wood, bamboo. Artificial fibres include polyester, rayon, nylon, Kevlar®, lyocell (Tencell®), polyethylene, polypropylene, polyimide, polymethyl methacrylate, Poly (Carboxylato Phenoxy) Phosphazene PCPP, fibre glass (glass), ceramic, metal, carbon. The article of clothing may be selected from the group consisting of face masks (surgical masks, respirator masks), hats, hoods, trousers, shirts, gloves, skirts, boilersuits, surgical gowns (scrubs) etc. Such clothing may find particular use in a hospital where control of infection is important.

According to another embodiment, there is provided a method for the reduction and/or prevention of virus transmission, comprising applying a composition of nanoparticles as defined above to a filter. The application of the composition of nanoparticles may be via a plasma treatment or plasma polymerisation process.

Referring to FIGS. 6 to 9, there are illustrated embodiments of an article 1, which is shown as substrate 200. The substrate 200 may be a film, a textile, a fabric, or any other desired generally planar surface. A pathogen inhibiting layer can be applied to the substrate 200 by the system 10. The pathogen inhibiting layer may be a first coating 210 or second coating 220, for example. While it is preferred that a planar surface is treated with a coating, the coating can be applied to irregular or textured surfaces or three-dimensional objects such as electronics or peripherals therefor. More than one coating may be applied to a surface of an object or substrate 1 to create a desired functional or pathogen inhibiting treatment.

A textile or fabric may include at least one of; nylon, polyamide, rayon, polyester, PP, PET, PE, aramid, acrylic, acrylate, paper, wool, silk, cotton, linen, Kevlar®, lyocell (Tencell®), fibre glass, glass, woven textiles, non-woven textiles, knitted textiles, braided textiles, insulation materials, synthetic materials and fibres, natural materials and fibres, organic materials or any other material which may be suitable for use in a garment, PPE, face mask, filter, drapes, bedding, wall covering, and upholstered products. It will be appreciated that a textile is a substrate 200 formed with yarns, filaments, strands or fibres which are interconnected in a regular or ordered manner (woven or knitted textiles) or bonded together in the case of non-woven textiles. These textiles have pores or gaps between fibres, yarns, filaments, or strands, which makes these textiles breathable which is a highly desired property for garments, and for a number of filtration devices and mediums.

Gaps and pores of a textile may also increase the overall surface area of a side of the textile and therefore pathogen inhibiting layers applied thereto may also have a generally larger surface area which may be advantageous for catching, or inhibiting pathogens. The pathogen inhibiting layer may also be formed such that the overall surface area is increased or has at least one texture to increase the surface area compared to more effectively inhibit pathogens. A pathogen inhibiting layer may have variable thicknesses to allow for different pathogen inhibiting applications or periods of pathogen inhibiting potential. For example, a relatively thicker pathogen inhibiting layer may allow for a longer period of pathogen disruption compared to that of thinner pathogen inhibiting layers or compared to that of conventional coatings which include dispersed nanoparticles.

While silver and copper have been shown to provide such denaturing effects, other inorganic materials may also have a number of benefits which can be used for self-cleaning, self-sterilisation, biocidal, pathogen inhibiting, pathogen-killing or oligodynamic effects.

Other metals and inorganic materials which may be used may be selected from the following group; titanium, aluminium, zinc, gold, cesium, copper; sulfates of calcium, strontium, barium; zinc sulfide; copper sulfide; titanium dioxide and barium zeolites; mica; talc; kaolin; mullite or silica. In addition, lead or mercury compounds may also have some use depending on the application. The average diameter of the metals deposited may be between 0.01 and 200 microns, preferably in the range 5 to 100 microns.

The textile receiving the metal coating may be inorganic particles having a first coating of a metal or metal compounds and a second coating layer of silica, silicates, borosilicates, aluminosilicates, alumina or mixtures thereof.

The inorganic particles, i.e., core material may be any of the oxides of titanium, aluminium, zinc, copper; calcium, strontium, barium and lead. Optionally as suggested, the materials may be sulfides or sulfates. It is preferred that a near pure metal or a metal alloy can be used to form a nanoparticle for the pathogen disruptive layer. However, it will also be appreciated that other compounds may be used, such as silver nitrate (AgNO₃), or titanium dioxide (TiO₂).

The term “pathogen disruptive layer” will be used herein to describe a material which has been deposited by a plasma method or plasma polymerisation method. This material may include any of the inorganic materials above and be used to kill, disrupt, inhibit, or otherwise destroy pathogens which come into contact with the deposited surface, or an ion released therefrom.

The pathogen disruptive layer can be deposited onto the substrate through a chemical vapor deposition, a physical vapor deposition, or a sol gel deposition, or a combination thereof. The pathogen disruptive layer may be a first coating, and/or a second coating, and/or a further coating applied to an article 1.

Application of a pathogen inhibiting layer onto a substrate 200 may provide for an enhanced pathogen inhibiting substrate. Further, the combination of a pathogen inhibiting layer textile and pathogen retaining or dirt/chemical retaining filter medium offers various functions including, but not limited to; pathogen control, chemical control, and dirt control while maintaining a low pressure drop and a high water flow rate when in use. This may be of particular use for air filtration, water purification and filtration, and other fluid capture and cleaning applications. This may also be of particular use in laboratory extraction systems and for personal protective equipment, face masks and clothing. Further, as the coatings may be applied to generally sterilise or decontaminate a surface of a mask, previously single use masks or gowns used in medical settings may be used multiple times without any or significant degradation of filtration or safety quality. This is of particular advantage with regard to face masks for seasonal influenza, colds, COVID strains, or any other viral filtration devices.

The filter medium may be any substrate which can filter, retain or capture particles which move into the same plane as the filter medium. The filter medium may be charged with a positive or negative charge to attract particles of the opposite charge. Additionally, the filter medium may be a non-woven material or a generally porous material which can allow desired fluids to pass while capturing pollutants or other particulates. A pathogen inhibiting layer can be applied to the filter medium directly or may be combined with the filter medium to form an article 1. It will be appreciated that the article 1, in some embodiments, may be a filter medium with at least one coating applied thereto, wherein an applied coating is a pathogen inhibiting layer.

The combination of a pathogen inhibiting layer and a filter medium may be desired as the filter medium can be used to capture and retain the pathogen to allow for an effective time period for the pathogen inhibiting layer to kill, disrupt, inhibit, or otherwise destroy pathogens captured. In addition, it is preferred that the gaps between fibres or the pore size of the filter material is as large as possible for some applications, such as for filtration masks, to allow a desired breathability. However, having a larger gap or pore size may reduce the potential to physically capture particulates and therefore charged fibres may be used to draw particulates to the filter medium and retain the particulates.

In another embodiment, there may be provided a filter substrate or filter medium. The filter medium may comprise a silver or copper coated textile with at least one functional treatment applied thereto. It will be appreciated that any of the pathogen inhibiting depositions mentioned herein may be applied to a filter medium. Optionally, a membrane may be included which can be used to filter and/or capture dirt, and/or a chemical-retaining membrane, and/or pathogen-retaining membrane, or a combination thereof. The membrane can be disposed between the substrate and a coating, such as that the coating is applied directly to a membrane. The membrane may be integrally formed with substrate 200 or may be fixed or adhered to the substrate 200.

Further, the invention, in at least a preferred embodiment, relates to the use of textiles which are coated with a silver deposition (or other biocidal material). The textile can be used for forming a pathogen-retaining filter medium, for providing filter medium with enhanced pathogen killing efficacy and for pathogen disruptive or pathogen inhibiting protective equipment.

Accordingly, a preferred embodiment of the invention provides filter medium comprising a microorganism-killing membrane. The microorganism-killing membrane includes a textile deposited with at least one pathogen or microorganism disruptive membrane. It is preferred that the filter medium does not contain an adhesive layer or adhesive pastes which could cause blockage of the pore or gaps for the textile or membrane.

If the substrate 200 is a non-woven material, the non-woven material may be a sheet structure of continuous filament polyester or polypropylene fibres that are randomly arranged, highly dispersed, and bonded at the filament junctions. The chemical and thermal properties of spunbonded polyester are essentially those of polyester fibre. The fibres' spunbonded structure offers a combination of physical properties, such as, high tensile and tear strength, non-ravelling edges, excellent dimensional stability, no media migration, good chemical resistance, and controlled arrestance and permeability. Spunbonded polyester or polypropylene fabrics are used in various industries as covers (e.g., medical gowns or masks) or support materials. These may also be utilised in the medical industry and also for other personal protective equipment or disposable products.

Spunbonded polyester or polypropylene fabrics include either straight or crimped or polypropylene polyester fibres which give the fabrics different filtration and other general performance properties. It is believed that crimped fibres offer properties of softness, conformability, and greater porosity, while straight fibres yield stiffness, tighter structure, and finer arrestance.

The pathogen inhibiting layer of the present invention may provide for a surface that can reduce activity of pathogens and thereby reduce the persistence of potentially dangerous pathogens on surfaces. For example, the Sars-COV-2 virus has been shown to persist on some surfaces for several days, when exposed the treated textile, its persistence may be reduced to between 5 to 60 minutes. It is preferred that up to 99.9% of pathogens exposed to the surface are deactivated after a period of 60 minutes.

Optionally, the substrate 200 may be formed with at least one antibacterial or anti-pathogen chemical or nanoparticle within a fibre structure if the substrate comprises fibres. For example, a fibre of the substrate 200 may include silver or copper nanoparticles which may also release ions in addition to the pathogen inhibiting layer.

In one embodiment, nanoparticles may form at least a part of a continuous coating or film which can conform to the general surface topography of the substrate 10. The nanoparticles may be protected, covered, or have a functional coating applied thereto after deposition which can assist with reducing nanoparticles from becoming dislodged from the substrate 10. Properties of functional coatings may include at least one of; flame retardant, UV absorbing, self-cleaning, hydrophobic, hydrophilic, and/or antibacterial. Other functionalisations may also be applied as is known in the art.

The reduction and/or prevention of virus transmission may be defined as a reduction of infectious viral titre of a virus of known concentration by at least 99.9% after exposure to the treated fabric. Preferably the reduction of infectious viral titre is at least 99.9%, 99.99% or 99.999%. Reduction and/or prevention of virus transmission is demonstrated by the inactivation of virus after exposure of the virus to the treated textile.

In other embodiments, the nanoparticles may suitably be formulated in an appropriate carrier, coating or solvent such as water, methanol, ethanol, acetone, water soluble polymer adhesives, such as polyvinyl acetate (PVA), epoxy resin, polyesters etc, as well as coupling agents, antistatic agents. Solutions of biological materials may also be used such as phosphate buffered saline (PBS), or simulated biological fluid (SBF). The concentration of the nanoparticles in the solution may in the range of from 0.001% (wt) to about 20% (wt). These nanoparticles may then form a coating which can be applied to the substrate 10.

In yet another embodiment, the article 1 may comprise more than one pathogen inhibiting layer which can release ions to inhibit pathogens. It may be advantageous to allow for multiple pathogen inhibiting ions to be present at a surface to more effectively inhibit a pathogen.

In a further process, an article 1 may be treated by a physical vapour deposition (PVD) or chemical vapour deposition (CVD) process in advance of being treated by the system 10. A plasma enhanced PVD or CVD process may also be used if desired, and may be referred to herein as “PVD” and “CVD” only. Materials applied by either PVD or CVD methods may be in the form of a film, or a generally uniform coating.

As such, a method for coating a PVD or CVD film is anticipated by the present disclosure. During this treatment, the electrodes 100 are relatively displaced from the article 1 with the PVD/CVD coating, such that adverse plasma conditions are prevented, or otherwise limited. For example, corona discharge or other plasmas which could damage an article 1 may form in the presence of conductive materials or surfaces.

A primary advantage of applying a film using the above methods is that the overall thickness of the coatings may be in the nano-scale to micro-scale, and the use of adhesives may also be entirely removed as adhesion is property of the vapour condensing onto a substrate which can provide for atomic bonding. This may also assist with reducing the distance between layers of a composite material or a multi-layer structure allowing for statically charged materials to be relatively more effective when combined with at least one of a PVD/CVD film or coating and/or an antipathogen coating. Another advantage may be allowing for a relatively thinner and more flexible structure to be formed as adhesive may reduce the overall properties of the structure formed. While it is noted that adhesion is dependent on the mechanical properties of the two materials brought into contact, the use of a vapour deposition may provide for at least a weak bond which can be encapsulated or protected by a further coating or treatment, such as the coating which can be applied by the system 10. The bonding may also be impacted by the relative contact angle of the vapour to the substrate and the temperature of the vapour and condensation rate.

Metal nanofilm morphology of a film applied to an article 1 may also play a large role for a number of properties, such as antipathogen properties, conductive properties, surface roughness, reflectivity, aesthetic properties, and the like. As such, the system 10 may be used to apply a coating which may protect a film or coating applied by PVD/CVD processes, which may also assist with reducing the rate of oxidation or chemical change of one or more other properties of the film. Further properties may be imparted by the plasma coating from the system 10, such as hydrophobic coatings. A significant advantage of applying a thinner coating from the system 10 is that emissivity properties of the applied films may be negligibly impacted by the addition of a protective coating, or have generally no observable impact on the emissivity of a film. In this way, superior reflective and low emissivity surfaces may be created, which cannot be achieved by processes currently in the art.

In addition, as PVD, CVD and system coating methods can all be applied as one sided coatings (i.e. are not dipped or otherwise encapsulated by a treatment) the methods described may have primary advantages for imparting desired properties to one surface of a substrate, while leaving a second surface of a substrate to be generally the same prior to deposition or coating. Such methods are not available in the art, let alone available to coat with such a relatively thin thickness of coating.

Optionally, multiple layers of films and plasma coatings may be applied in any desired configuration. Plasma coatings may also be applied in advance of PVD or CVD processing such that improved adhesion may be obtained, or a protective coating may be applied to the substrate in advance of being deposited with a metal film or coating. Optionally, the PVD or CVD coating is sandwiched between two plasma coatings, and may be used as a conductive layer for e-fabrics or other desired conductive materials.

Films deposited may also be etched by a plasma coating or by a plasma treatment. Such etching may be applied with a plasma stream to focus etching locations, or applied with a stencil. Other etching techniques may be used to selectively etch at least a portion of a metal film. Etched regions may be filled with an organic, or inorganic nanoparticles or pigments. Optionally, a layer above and below the metal film may be used to etch the metal film applied.

In another embodiment, the application of a pigment or nanoparticle to an article 1 may have an evaporation step or other removal step to remove solvents, gels, dispersions, or solutions which the nanoparticle or pigment was supplied within. After this removal step, the article 1 with nanoparticle or pigment may be treated with a plasma treatment before being coated with a further step of a plasma coating. It will be appreciated that a plasma treatment may be used before the application of a nanoparticle or pigment, after the application of a nanoparticle or pigment, and after a plasma coating has been applied. Each of the plasma treatment steps may be adapted to assist with fixation of the pigment or nanoparticle, and may also be used to imparta desired functionality or property to at least one of the nanoparticle, pigment or plasma coating.

Optionally, more than one coating of the same material can be made to a substrate 200 with the first coating being applied to the substrate upper surface and the second coating being applied to the upper surface 212 of the first coating 210. Alternatively, the first and second coatings 210, 220 can be applied to the upper and lower surfaces of the substrate 200. It is clear that in these two extreme cases, continuing the deposition, films of the same material will be formed but with very different nanoscale structure and morphology and, as a consequence, with very different properties such as density, adhesion behaviour, etc. Optionally, pathogen inhibiting layers may be disposed under a self-cleaning layer such that the surface of the article 1 can self-clean (such as remove oil stains) and also inhibit pathogens which contact the article surface.

For example, a self-cleaning TiO₂ or AgNO₃ layer may be applied over a pathogen inhibiting layer such as a layer containing copper or silver ions. The ions from the silver or copper layer may diffuse to the upper surface of the self-cleaning layer and promote an adverse environment for bacteria, microorganisms, viruses or other biological matter. Alternatively, the self-cleaning coating may be the primary coating applied to an article 1 which provides a self-cleaning coating. When exposed to sunlight these coatings may react with water to generate hydroxyl radicals. These radicals may break down organic molecules and microbes adsorbed on the surface of the coating. Fluids, such as water, may be applied to the coating which can be absorbed and allows for dust, dirt, oil, and other contaminants on the surface to be removed, or substantially removed. Other self-cleaning coatings may also be applied, and may have different activation or cleaning reactions, however it will be understood that any self-cleaning coating may be applied by the system 10.

Self-cleaning coatings may have applications for garments, medical devices, commonly touched articles, vehicles, aeroplanes and public facilities. Multiple coatings may be applied, or reapplied, to an article 1 such that desired properties can remove dirt, stains, oils, or other predetermined contaminants.

It will be appreciated that the use of magnetic nanoparticles or coatings to form a pathogen inhibiting layer may exhibit superparamagnetism properties when particle sizes are less than around 20 nm in diameter. As such, the management of particle sizing may have applications which extend beyond pathogen inhibition properties or may be supplemental to said pathogen inhibiting properties. For example, electronics may have particular use for superparamagnetism properties.

The article 1 of the present invention may also have utility as an air or water filter medium. These filters may be used to purify fluids or capture undesired contaminants in fluids. The filter medium is preferably formed from a substrate with at least one of a pathogen-retaining medium and a pathogen inhibiting layer. Optionally, the pathogen inhibiting layer in this embodiment may be a membrane or is deposited/applied onto a membrane which is used in the filter medium. Optionally, the membrane may be an article 1 comprising a substrate 200 and at least one coating formed via a plasma polymerisation process.

In another embodiment, the article 1 may be a protective barrier such as a gown, a wall covering, drape, a curtain, a sheet, or another substrate used for creating a barrier to an environment or barrier to reduce or inhibit penetration of a fluid or a particle in a fluid, such as a pathogen.

A pathogen retaining medium may be used to capture pathogens by either providing a physical barrier or providing a static charge which can attract and capture pathogens. This is due to pathogens having a charge which can be attracted by a statically charged substrate. At least one pathogen retaining medium may be included within the article 1 and a coating, which can be a pathogen inhibiting layer, may also be included to allow for capture and then inhibition or destruction of pathogens by the article 1. It will be appreciated that the protective barrier and the filter medium may be constructed from the same substrates and coatings. As such, the references herein to the term “filter medium” may also refer to “protective barrier”. Any pathogens which may be captured or caught by the pathogen retaining medium may be killed, or inhibited, by ions from the nanoparticles in the coating, or by the chemistry of the coating if it is viricidal or biocidal.

The filter medium may further comprise a dirt or chemical holding filter medium for capturing larger particles before the larger particles interact with a pathogen inhibiting layer to reduce potential biological fouling of the filter. The term “biological fouling” herein means accumulation of microorganisms on surfaces or pores of the pathogen inhibiting layer or another coating associated with the filter medium.

In another embodiment, there may be provided a filter medium (not shown) containing at least two membranes with or without pathogen inhibiting layers. The membranes may also be suitable for limiting the flow of fluids. Each membrane may be bonded with a substrate 200 or a pathogen inhibiting layer. Adhesives for fixing substrates and membranes may reduce the mechanical properties of the membrane and therefore may be disadvantageous to use. However, thermally bonding the membrane and a substrate 200 together may overcome these drawbacks. Additionally, utilisation of a nonwoven intermediate layer (not shown) may be used as a bonding layer to reduce adverse impacts on the membrane of the filter medium.

Optionally, the filter medium may restrict fluid flow in a first direction and promote fluid flow in a second direction. In this way filter mediums may be bidirectional filter mediums which can be inserted into conventional filter cartridges or other filter holding devices. For example, the filter membrane may have utility as a water purification filter medium or a filter medium which can be mounted within an air-conditioning unit. Other applications for the filter medium may include respiratory devices, masks, a water storage tank, a pump, a supply line, a water-purification device furniture textiles, flooring foundation, geotextiles, or other applications where filtration and pathogen inhibition are desired.

In one embodiment, the filter medium may be an air filter. An air filter may be used to remove contaminants, often solid particles, from air. Air filters are often used in diving air compressors, ventilation systems and any other situation in which air quality is important, such as in air-conditioning units. An air filter includes devices which filter air in an enclosed space such as a building or a room, as well as apparatus or chambers for handling viral materials. Other articles which perform a protective function such as curtains or screens may therefore also be considered as air filters.

Air filters may be composed of paper, foam, cotton filters, or spun fibreglass filter elements. Alternatively, the air filter may use fibres or elements with a static electric charge. There are four main types of mechanical air filters: paper, foam, synthetics and cotton. Any desired substrate of the article 1 may be charged with either a positive or negative charge. As most viruses are generally negatively charged, the substrates may be positively charged such that the substrates, or fibres thereof, can attract viruses and capture viruses to be inhibited or destroyed by ions of a pathogen inhibiting layer. This is also advantageous as charged fibres can allow for a more open, and therefore more breathable, substrate to be formed which can capture particles, including viruses, with more than just physical means.

In another embodiment two or more substrates 10 which may be laminated together. Each respective substrate may have a unique construction before lamination. The resulting article 1 may be a construction which is suitable for medical filtration applications, such as for use in gowns, surgical masks, curtains or the like. The lamination of multiple layers of substrates (with or without coatings) can be used for a number of applications and may allow for inclusion of multiple pathogen inhibiting layers of different structures and compositions. More than two substrates can be laminated to achieve a higher filtration performance or an improved disinfection performance. It will be appreciated that the term “disinfection” herein refers to the cleaning or removal of a pathogen from a surface by inhibiting, capturing, killing or otherwise destroying said pathogen. Disinfection may take seconds to hours depending on the pathogen disruptive layer properties and the age or surface topography of the pathogen disruptive layer.

In another embodiment, the article 1 may be a barrier which includes a one or more substrates 200 and at least one coating on a substrate 200. Each respective substrate 200 may have a unique construction which can be used for any desired functional purpose, such as hydrophobicity, hydrophilicity, statically charged, pathogen inhibiting or any other predetermined function. Similar to laminated articles mentioned above, the article 1 may be a construction which is suitable for barrier applications which may include for use in gowns, surgical masks, curtains, or the like. Multiple substrates, which may each respectively have one or more respective coatings thereon, can be used for a number of applications, such as forming a protective barrier. Protective barriers may be used for a number of applications such as use for; gowns, curtains, bedding, or used for creating any other desired barrier to an environment. More than one substrate may be used to impart a desired filtration, or improve the filtration performance or improve the disinfection performance of the article 1.

Accordingly, the invention provides more efficient disinfection filter medium for air or liquid filtration. The filter may be formed to provide any desired property, such as a low pressure drop and a high flow rate when in use. It is preferred that the substrate may have an air permeability that allows a differential pressure of less than 4 mm H₂O/cm² through the substrate. Preferably, any filter material is treated with a pathogen disruptive layer. While the textile may comprise at least one pathogen disruptive layer, any number of pathogen disruptive layers can be used. Each of the pathogen disruptive layers may be formed from the same material or same pathogen inhibiting or pathogen killing material. A stacked arrangement or stacked configuration may be used with the textile which can be used to kill, filter, capture, reduce movement, inhibit, disrupt or otherwise intervene with the progression of a pathogen into the respiratory system of a person.

The use of nanoparticles may be disadvantageous for a number of applications as the bonding energy between a substrate and a nanoparticle applied through conventional methods is relatively weak, and therefore leaching can occur in use. Leaching silver or other inorganic nanoparticles can have a number of problems and environmental impacts or health impacts for a wearer. For example, silver leaching into water systems can increase algal bloom and cause ecosystem imbalances, or the consumption of silver can cause silver poising (argyria) which can cause permanent discolouration of the skin. As such, the application of a nanoparticle within a polymer matrix can be used to increase the overall bonding strength between a substrate and the nanoparticles deposited relative to conventional solution dipping or padding methods or thermal bonding methods known in the art.

The filter medium may be prepared from any suitable natural or artificial material as described above in relation to at least one embodiment. It is preferred that filters are formed from generally porous materials which can capture particles of any predetermined size.

Polyester fibre can be used to make web formations used for filtration devices and filter mediums. polypropylene or a polyester blended with cotton may be used to produce the filter medium. Other fibres may also be substituted for the cotton in the blended article 1. Tiny synthetic fibres known as micro-fibres may be used in many types of HEPA (High Efficiency Particulate Air Filter) filters. High performance air filters may use oiled layers of cotton gauze.

Alternatively, the filter may be used to filter liquids. Such filters may be composed of any suitable fibre as described above. Filters used to filter liquids may be used to filter potable liquids for human or animal consumption, water for general domestic use, fluids for medical use, such as plasma or saline solutions, or pharmaceutical formulations for injection, or other biological liquids which may come into contact with a patient.

According to another embodiment, there may be provided an article of protective clothing composed of fibres in which said fibres are coated with a composition of nanoparticles as defined above. The personal protective clothing may be any item of clothing which can utilise the article 1 of the present invention or benefit from a coating or treatment which is applied with a plasma treatment process to form a pathogen inhibiting layer. For example, the personal protective clothing may be a face mask. Such masks may cover the whole face of the user or a part thereof, suitably the external areas of the nose and/or mouth of the wearer.

In a preferred embodiment of the present invention there is provided a face mask or a filter composed of a fibrous non-woven material which has been coated with a pathogen inhibiting layer via a plasma treatment method. The pathogen inhibiting layer may be a composite material with one or more layers bonded or fixed together to form an article 1. The article 1 may form at least a portion of the mask or filter. Optionally, a gel, cream or other solution can also be applied to an article or an article with a coating which comprises pathogen inhibiting ions (such as nanoparticles of silver or copper) which can be used to kill or reduce activity of at least one pathogen. For example, the use of mixed nanoparticles of zinc oxide (ZnO) and titanium dioxide (TiO₂) for reducing and/or preventing virus transmission. Such mixed nanoparticles of the invention may also be used in methods as described above, or in filters as described above, or articles of protective clothing as described above.

In yet a further embodiment, there is provided a method of preparing a filter. The filter may be used for at least one of; air filtration and water filtration. The method comprises thermally bonding silver or copper coated substrates 200 with a thermal bonding layer, optionally including a pathogen-retaining medium such as a non-woven material. Thermal bonding may be conducted through at least one of the following processes selected from the following group; calendaring, belt calendaring, through-air thermal bonding, ultrasonic bonding, heat bonding, lamination, and autoclave processes.

If the article 1 is to be used to form a garment, the garment may be selected from the group consisting of face masks (surgical masks, respirator masks), hats, hoods, trousers, shirts, gloves, skirts, boilersuits, surgical gowns (scrubs) etc. Such clothing may find particular use in a hospital where control of infection is important.

It is preferred that the plasma temperature is less than the melting temperature of the article to be treated, or the article 1 is exposed to the plasma for a period of time which is not sufficient to melt or otherwise plastically deform the article 1. Application of a pathogen disruptive layer may optionally be before the article 1 is exposed to the plasma of the module 20, or may be applied when the article 1 is within the treatment area of the module. Preferably, the electrodes 100 are disposed to one side of the article 1, and the article is not relatively between the electrodes 100 forming the plasma.

Also disclosed is a method of coating nanofiber fabrics with a thin biocidal coating. The method includes a step of depositing a biocidal material, such as a film or coating, resulting in nanoparticle-coated article 1.

In one embodiment, the method includes the steps of positioning an article relatively below a treatment module; purging local atmosphere between the article and the treatment module; supplying a plasma fluid to an electrode region of the treatment module, the electrode region comprising two or more electrodes; igniting a plasma gas to form a plasma in the electrode region; and supplying at least one of a monomer and a nanoparticle to the plasma in the electrode region, such that the monomer is polymerised by the plasma and the nanoparticles being fixed to the article by polymerisation of the monomer as it forms a coating on the article.

In yet another embodiment, the nanoparticles may be an inorganic copper salt. The term “inorganic copper salt” includes inorganic copper compounds that are relatively insoluble in water. Inorganic copper salts are ionic copper compounds whose cations together with anions of other inorganic substances form this compound. When such salts are placed near water, these compounds usually release copper ions (Cu+ or Cu++). Copper salts with low water solubility, i.e. less than 100 mg/L and less than 15 mg/L are desirable. Such desirable copper salts include copper halides, cuprous oxide and cuprous thiocyanate.

The term “copper cation release” generally refers to providing a copper cation from a metal salt suspended by a functionalizing agent to the environment in which the microorganism is currently located. In one embodiment, the release occurs, for example, when copper ions dissolve from the copper halide particles. In another embodiment, release is mediated by a functionalizing agent such as PVP. PVP forms a complex of copper cations until it contacts microorganisms and moves the cations to its external environment. Any number of mechanisms can cause the release of copper cations, and the present invention is not limited to any mechanism. In addition, a potential antibacterial effect is the release of anions from copper halide particles, for example, triiodide anion (I 3−) is a known antibacterial agent.

Different salts have different water solubilities and may be used to impart a desired release profile of the antipathogen properties from the coating. For example, sodium chloride, zinc iodide, sodium citrate, sodium acetate, and sodium lactate can be added to a coating which includes sliver nitrate to produce a coating which contains the water-soluble salts. By adjusting the proportions of salts having different solubilities in the composition, the release rate of the antipathogen can altered to provide a shorter or longer release profile over time. These salt materials may have a benefit when being used as, or with, wearable articles 1.

In another embodiment, a silver salt solution can be converted into an aerosol which may then be delivered to a plasma region. Silver molecules from the salts can be fractionated and elemental silver nanoparticles may be deposited onto the article 1. “Silver nanoparticles” means particles composed mainly of silver metal and having a particle size of about 1 micrometre or less. Silver in the nanoparticles can be present in one or more oxidation states thereof, such as Ag⁰, Ag¹⁺ and Ag²⁺.

A relatively “heavy” molecular weight monomer may be required to carry a metal particle or metal salt. The molecular weight of the monomer may be required to be greater than 160 g/mol to classify as a heavy molecular weight monomer within the context of this disclosure.

In yet a further embodiment, the sol-gel may be prepared as a high solids solution and used alone or mixed with other polymers. Polymers may include at least one of the following group; natural and synthetic rubber, especially latex rubber, acrylonitrile rubber, PVC plastisol, PVC, polyurethanes, silicone, polycarbonates, acrylates, polyamides, polypropylenes, polyethylenes, polytetrafluoroethylenes, polyvinylacetate, poly (ethylene terephthalate), polyesters, polyamides, polyureas, styrene-block copolymers, polymethyl methacrylate, acrylic-butadiene-styrene copolymers, polystyrene, cellulose, and derivatives and copolymers of any of the above.

A high solids solution may have particular advantage for medical devices, and may be applied to latex rubber for fabrication of catheters, gloves, and other dipped latex products by standard form dipping methods, and vinyl plastisols can be mixed with compositions of the invention to provide dippable and castable antimicrobial PVC devices. Application via a plasma treatment process allows for an appropriate coating to be formed and also simultaneous drying or curing of the coating which cannot be achieved by conventional dip methods.

The first coating conferring antimicrobial properties may be metallic silver or copper or compounds of silver, copper and zinc which have extremely low solubility in aqueous media. The antimicrobial component may also be an alloy of silver with copper or zinc. The antimicrobial component should release silver, copper or zinc ions at an effective level of antimicrobial activity. For example, an effective level of antimicrobial activity may mean a minimum of 2 log reduction within 24 hours in a shake flask test, over a prolonged period of time, such as months or preferably years. Components which meet these criteria are silver, silver oxide, silver halides, copper, copper (I) oxide, copper (II) oxide, copper sulfide, zinc oxide, zinc sulfide, zinc silicate and mixtures thereof. Mixtures of silver with zinc silicate and silver with copper (II) oxide are preferred. The amount of antimicrobial component on the core particle is in the range of 0.05 to 20% by weight, preferably 0.1 to 5% by weight based on the particle core material. A surprising feature of the present invention is that these powders confer activity at loadings of the metals which are substantially lower than those achieved by the prior art materials. This is achieved despite the use of protective coatings to encapsulate the antimicrobial components. In carrying out this invention, the core particles may also be optionally precoated with alumina in the amount of about 1 to 4% to ensure good antimicrobial properties after precipitation of the antimicrobial components.

A secondary protective coating may be selected from silica, silicates, borosilicates, aluminosilicates, alumina, aluminum phosphate, or mixtures thereof. The secondary coating functions as a barrier between the antimicrobial particle and a polymer matrix in which it may be incorporated, minimizing interaction with the polymer. This secondary coating also is believed to influence the rate at which the antimicrobial component diffuses from a dispersed particle into the polymer matrix.

Optionally, a monomer may be present which can polymerise to form a coating in which the nanoparticles or pigments are distributed. The nanoparticles may be activated upon introduction into the plasma region, and may bond with the polymer formed in the plasma. In this way the nanoparticles may be adhered to a surface more readily, and may reduce the potential for nanoparticles to be dislodged.

Some nanoparticles may be encapsulated by the polymer, while others are embedded or partially embedded to the polymeric coating. Pigments may similarly be encapsulated, embedded or partially embedded by plasma polymer coating. If nanoparticles are encapsulated within the atomised state, the nanoparticles may have an insulative barrier which can reduce the potential for corona discharges or adverse plasma conditions forming if the nanoparticle is a conductor. For example, aluminium or copper nanoparticles are conductive and upon entering into the plasma region may cause instability of the region. Therefore, it is desired that the particle are either of a size and/or distribution which does not cause adverse plasma conditions, and/or the nanoparticles are encapsulated or insulated by the monomer during the plasma polymerisation process. Nanoparticles may also be non-conductive until being activated by a charge, a plasma, or a chemical reaction.

The morphology and topography of the surface of the pathogen inhibiting layer may also provide improved benefits in relation to the diffusion of ions and the effectiveness of pathogen disruption. Further morphology and topography may allow pigments to be more or less visible and either dull or improve a shine to a pigment which may impact colouration provided by the pigment.

The topographical features and morphological features of the surfaces of the first coating and/or the second coating may have a significant impact on the diffusion rate of ions from the pathogen inhibiting layer. The relative distance between the nanoparticles and the upper surface of the coating may also impact the diffusion rate of ions from the nanoparticles. Preferably, the ions from the nanoparticles are drawn to the exposed surface of the coating such that they may more effectively inhibit pathogens which interact with the article 1.

Surface roughness of the coating is preferably in the range of 0 nm to 100 nm. Height differences between valleys and peaks formed on a surface will define the surface roughness, with the roughness parameter quantifying the vertical spacing of a surface, neglecting the horizontal spacing. If the vertical spacing are large, the surface is rough; if they are small the surface is smooth. Relatively speaking surface roughnesses of greater than 50 nm (median) are considered rough and less than 50 nm (median) are considered to be smooth.

It will be appreciated that nanoparticles at the surface of the coating may protrude higher than the medium surface height and may increase the overall surface roughness if the percentage of nanoparticles is relatively high.

In another embodiment, the system may be used to apply a further coating or treatment to an article 1 if desired. For example, a monetary note may be frequently circulated and could have pathogens at the surface which can be transferred to other persons touching the note. As such, it may be desirable to apply a pathogen inhibiting treatment to a monetary note such that the notes can be circulated with a reduced risk of pathogen transference. In this example, a bank or other predetermined location which handles a relatively large volume of money may use the system to apply a coating or treatment to the notes or coins to impart a transparent or other essentially non-visual coating to the notes and/or coins which can reduce the persistence of a pathogen. This may assist with reducing the chance of pathogens remaining on the note or coin.

Optionally, the system may log or record the serial number of notes which have been treated, such that exposure to further coatings can be reduced if they have been treated relatively recently. Records of treated notes can be communicated to the relevant regulatory bodies for moneys.

In another example, the system may be adapted to treat or retreat articles 1 which are exposed to varying conditions, which may assist with maintaining functionality when in use. For example, exterior facing plastics, woods and metals of vehicles may commonly be subjected to water, dirt and other debris which can cause damage, blockages or other mechanical interferences. As such, it may be desirable to have a coating or treatment applied to these components of a vehicle to improve the reliability when in use. Coatings and treatments may be provided such that firearms may more easily pass a “mud test” or other similar test, where a component of a vehicle is covered completely with a mud, slurry or high moisture aggregate. The component is then used to determine whether there have been any blockages or failures. As such, having coatings which can reduce undesired matter from sticking to the surface of the component of a vehicle may provide significant advantage. The coating applied to the surface of the component may include nanoparticles, which may improve the gripability of the component (such as a handle), or may provide for an antibacterial or antipathogen treatment. Coatings may be dulled, or applied in a matt finish such that reflections from the coating are reduced.

As components may be stripped from a vehicle and cleaned or replaced, each component may be individually treated. This can be advantageous as some portions of a component may be require lubricants or other oils to be applied to allow for smooth operation. In other embodiments, the system is also adapted to apply a lubricant or other coating to an article 1, or portion thereof, which may last for a relatively longer period of time than conventional lubricants. In yet another embodiment, a surface of the component may be treated with an oleophilic coating to improve the adherence of oils to a desired component of a vehicle. Other machinery, motorised devices, outdoor equipment or articles which are subject to dirt, mud, water or other outdoor conditions may benefit from a coating applied by the system 10.

While reference has been made to components from a vehicle an article 1, any other article may receive a treatment of the system 10 to impart a desired functionality, or to dispose nanoparticles onto the article 1.

Articles 1 which are commonly touched or interacted with by persons may also be advantageously coated with a coating from the system 10. For example, doorknobs, phones, screen protectors, laptops, portable computers, tablets, bottles, gym equipment, car seats, public transport seating, aeroplane interiors, or any other articles 1 which are exposed to a large number of people. These articles 1 may be treated with an antipathogen treatment or coating, and may also optionally have a further coating applied which can be used to protect the antipathogen coating.

Due to the size of some nanoparticles and the ability of the system 10 to apply coatings in the nanometre thickness range, some coatings may allow for nanoparticles to protrude or otherwise project from the upper surface of the coating. These nanoparticles may be embedded in the coating, or extend through substantially entire the thickness of the coating. The nanoparticles may form nodes or ion releasing nodes which may inhibit, destroy or otherwise kill a pathogen.

Optionally, the support for articles 1 may be displaceable relative to the module 20, such that a desired distance can be achieved between the module 20 and the article 1 when being treated. In another embodiment, the module is adapted to determine the relative location of the article in the system, and may automatically raise or lower the position of the electrodes or the module 20 may be raised or lowered to a desired height based on the treatment being applied and/or the geometry of the article 1. The module may also be adapted to perform a sweeping motion within a chamber 15 to conform to a contour of the article 1 to be treated. This may be of particular advantage if the article comprises an undulating, irregular or non-linear geometry, or if a linear geometry of an article 1 is at an angle which is not parallel with the module 20.

In yet a further embodiment, the chamber may be purged with ozone (O₃) gases for a predetermined period of time, which may act as a pathogen inhibiting medium. The chamber 15 may then be cleared of ozone, and subsequently purged with an inert gas which will be suitable for a plasma treatment process. For example, the chamber 15 may be purged with an argon gas, which may also be the same as the plasma gas provided to the electrodes 100. In this way a two-step sterilisation and coating process can be conducted by the system 10.

Gases which are used to purge the chamber 15 may be captured and recycled for use within the system again. Contaminants in gases collected by a recycling system can be filtered out or removed from the recycled gases. Contaminants can be stored and disposed of offsite, or can be vented into atmosphere outside the system 10.

In yet a further embodiment, the article 1 may be a bandage or dressing with a coating applied thereto. The coating may be adapted to melt, dissolve or otherwise deform when exposed to body temperatures. This may be advantageous with regards to nanoparticles which may be embedded within the coating which are adapted to clean, treat or otherwise sterilise an area. These coatings may also be adapted to solidify after melting if the temperature is reduced below a threshold, which may then re-embed the nanoparticles within the coating, or reduce diffusion of ions from the nanoparticles. Optionally, the coating is an organic coating which can be absorbed by skin or other porous substrates. In one example, a bandage or other dressing may be coated with such a coating comprising nanoparticles, and be used to more effectively treat a wound or potentially infection area.

In addition, passing a monomer through a plasma region and then onto a substrate may allow for fractionation of the monomer and/or any nanoparticles therein. This can allow for a plasma polymerisation to be achieved, which can cause an increase in bonding sites relative to conventional UV, thermal curing or other coating curing methods. As a result, the coatings applied are generally superior to those of the state of the art, and may also be applied as a thinner coating overall. Thinner coatings have the benefit of reducing weight, reducing resource consumption and allowing for overall thinner composite materials to be formed.

The system 10 may be adapted to fully cure or partially cure a coating which is applied to an article 1. Fully curing the coating may provide for a hard coating, or a generally non-reactive coating which has a desired functionality. Partially curing a coating may also provide for a desired functionality, but may also leave the surface tacky, sticky, reactive or in an activated state. Partially cured coatings may be desirable for further coatings being applied to the partially cured coating, or may be desirable if the coating is to react or adhere to another coating or surface. Optionally, fully cured coatings may be activated by a further plasma treatment at a later time which may allow for a desired reaction or bonding to occur at the surface.

In addition, the coatings which can be applied by the system 10 may have a reduced impact on the overall breathability of a substrate 200 compared to traditional coating methods. This can also assist with maintaining a pre-coated flexibility or hand-feel.

In yet another embodiment, agglomeration of nanoparticles may also be induced when passing nanoparticles are fractionated within plasma region 112. This may allow for particles to adhere, combine, bond together or otherwise be in localised contact to function as a relatively larger particle. Particles exiting the plasma region 112 are preferably dispersed evenly onto an article 1 below. For example, several particles of 50 nm in length may agglomerate to form a particle which is up to 150 nm in length. However, it will be appreciated that the attraction forces between the particles may form a structure which is agglomerated in a more compact configuration, rather than a linear configuration. Other structures may be naturally occurring depending on the nanoparticle composition, and may cause laminations of agglomerations to be formed on an article 1 during deposition. Agglomeration can be used to increase the particle size being deposited, which may assist with forming coatings which have particles in the nanometre range to micron range. The size of the grains in the deposit may be similar or the same as that of the particles or pigment before being applied to the article 1 and the crystalline properties of the particles may also be preserved within the deposit.

In some embodiments, insertion of organic molecules or polymers into an anisotropic inorganic network may allow for 1D or 2D nanoparticle coatings to be applied to a surface of an article 1. Predetermined particles may be urged into a 2D on linear configuration, which can result in relatively thin surface coatings or molecular planar coatings. Linear configurations may be achieved with the use of magnetic fields adapted to order particles, or may be achieved by charging particles to self-order in a desired manner. Charging particles may be achieved during polymerisation, or subjection to the plasma region.

### Self-Cleaning

TiO₂ particles may be stabilised to effect a functionalisation. Stabilisation may be caused by temperature exposure and/or pressure exposure for an exhaustion method. Under UV or solar irradiation, coated polyester fabrics can decompose several organic dyes as well as coffee and red wine. The exhaustion process strongly stabilized TiO₂ NPs on the polyester, thereby enhancing the durability of loaded polyester fabric; nevertheless, the high temperature process required and had to be managed.

Optionally, functionalisation of TiO₂ anatase nanoparticles with 3-(Trimethoxysilyl) propyl-N,N,N-dimethyloctadecyl ammonium chloride (QASC) and 3-(Glycidoxypropyl) trimethoxy-silane (GPTS) in order to improve their adhesion to a cotton substrate. TiO₂ nanoparticles underwent an acidic hydrolysis process and a condensation reaction with QASC. Using the pad-dye-cure method, functionalized TiO₂ was dip-coated onto the substrate. Optionally, a substrate surface may be modified before the application of a coating, and or application of a particle.

It may be desirable to apply particles to the surface of a substrate in a solution, in which the solution is removed in a second step allowing the particles to remain on the surface of the substrate. The particles may then be fixed in place with a binder or coating. The coating is preferably a polymeric coating which is formed with a plasma treatment. More preferably the coating may be formed with a plasma enhanced chemical vapor deposition (PECVD) process.

While reference may be made to nanoparticles (NPs) throughout this specification the NPs may be instead be fine particles (FPs) which have a generally higher size in the micron range.

The use of TiO₂ within a siloxane coating may be also used in some configurations to modify the functionality of the siloxane coating.

It will be appreciated that the siloxane coating may be another superhydrophobic coating which loses the superhydrophobic performance with exposure to UV radiation. Optionally, the use of TiO₂ may also be used to alter a superhydrophobic surface to a hydrophilic surface with continued exposure to UV radiation. It will be appreciated that the TiO₂ may be activated by any UV radiation type.

The application of the coating may be applied via techniques including; layer-by-layer assembly, dip-/spray coating, and chemical wet process, were used to achieve a hydrophobic surface with a low surface energy. It may be preferred however that the coating is applied with a CVD process, which may be a PECVD process in which the coating is applied at the time of plasma exposure.

Plasma surface treatments allow for the modification of the chemical groups and topography of the treated surface. It can modify and improve surface properties without affecting the bulk properties of the material. It offers advantages over conventional wet surface treatments due to its dry-cleaning technique, which is both cost-effective and free of hazardous chemical applications.

Gases used to form a plasma are ionised within a predetermined region which may then be used to fractionate a precursor or may be used to break apart chemistry which is entered into the plasma.

The general temperature of the plasma region is preferred to be in the range of −100° C. to 200° C. More preferably, the temperature of plasma which may interact with a substrate can be controlled such that the temperature is limited to a temperature which is preferably below the melting point of the substrate to be treated. Preferably, the temperature is below a plastic deformation temperature of the substrate to be treated.

Plasma fluids which may be used with the system may include any noble gas, such as helium (He), neon (Ne), argon (Ar), krypton (Kr), xenon (Xe). Optionally, the plasma gases may include other reactive gases, which may include oxygen, hydrogen, nitrogen, air, fluorine gas (or mixture therewith), and water vapour. Other fluids may optionally be used if desired.

The electrodes which are used to strike the plasma may be any predetermined electrode. But may preferably include a dielectric barrier or dielectric sheath surrounding or partially covering an electrically conductive core of the electrode. The electrically conductive core may be any conductive material, such as gold, silver, copper, iron, steel, brass, aluminium or any alloys which include any of the aforementioned materials. Other conductive metals may be used if desired.

A monomer precursor can be fed into the plasma region to be fractionated and polymerised. Any predetermined monomer may be used, however it will be appreciated that HMDSO may be desired for some specific embodiments.

Other materials may also be introduced into the plasma region to be polymerised, such as oils. Oils may be selected from the following group: natural oils, synthetic oils, almond oil, orange oil, an oil from a citrus, nut oils, tree oil, tea tree oil, eucalyptus oil, and any other predetermined natural oil. It is preferred that the oil may be vapourised before introduction into the plasma region. Alternatively, the oils may be aerosolised such that they may be adapted to carry pigment or a dissolved material to the plasma region. Dispersants may refer to a solvent and a pigment therein which may be applied toa n article 1. Articles 1 which have a dispersion applied thereto may undergo a plasma treatment which may be used to fix a pigment to the Similar to the above, monomers are preferably vapourised, evaporated, or otherwise aerosolised. Optionally, a substrate surface may be modified before the application of a coating, and or application of a particle.

It may be desirable to apply particles to the surface of a substrate in a solution, in which the solution is removed in a second step allowing the particles to remain on the surface of the substrate. The particles may then be fixed in place with a binder or coating. The coating is preferably a polymeric coating which is formed with a plasma treatment. More preferably the coating may be formed with a plasma enhanced chemical vapor deposition (PECVD) process.

Nanoparticles may be nanomaterials as a natural, incidental, or manufactured material containing particles, in an unbound state or as an aggregate or agglomerate; where 50% or more of the particles exhibited, one or more external dimensions in the size range 1-100 nm.

The addition of particles on the surface may be in the range of 0.1% to 6% by weight relative to the applied plasma coating. Preferably the coating is used for fixing the particles to the surface of the substrate is a functional coating. Superhydrophobicity is of interest for practical applications such as water repellency, self-cleaning, stain resistance, antibacterial properties, and oil-water separation. In one embodiment of an experimental setup, a superhydrophobic coating a substrate is prepared by simple immersion in TiO₂ nanoparticles and perfluorodecyltriethoxysilane (PFDTS) solution.

A nanoparticle or pigment coating may be provided on the surface of a substrate by any desirable method. The methods may include dip coating, immersion coating, padding, spray coating, or any other conventional method. Liquids, solvents or dispersants may be removed and thereby leaving the nanoparticle or pigment on the surface of the article to be treated. Evaporation, heating, or other removal techniques may be used such that the article 1 to be treated remains with primarily a pigment or nanoparticle only, such that a second step plasma coating may fix said nanoparticle or pigment in place.

Preferably any particles on the surface on the substrate may be fixed to the substrate with a physical coating. Physical coatings may be a binder or other cement. It is preferred that the coating that is applied can be polymerised, but more preferably is applied with a CVD method wherein the precursor is fractionated before being applied to the substrate.

It may be preferred that the coating is formed with a hydrophobic functionality such that fluids can be repelled before staining materials proceed to the substrate. It may be desirable to have at least a portion of the particles in direct contact with the substrate such that the particles, such as TiO₂ can allow for a self-cleaning function to occur with exposure to UV light and/or oxygen.

Superhydrophobic coatings may have utility for self-cleaning, stain-resistant, antibacterial, and antifungal properties. Superhydrophobicity is a phenomenon where water droplets make a contact angle higher than 150±1°, and it can be seen in naturally found materials such as lotus leaf, rose petals, wings of a butterfly, and water strider.

The typical strategy for the fabrication of a superhydrophobic surface is the use of a hydrophobic material having a low surface tension along with nanoparticles. For superhydrophobicity, many nanoparticles like TiO₂, SiO₂, CuS, FeCl₂, carbon nanotubes, may be used to create roughness on the surface, which may be later coated with hydrophobic coatings, such as a plasma coating.

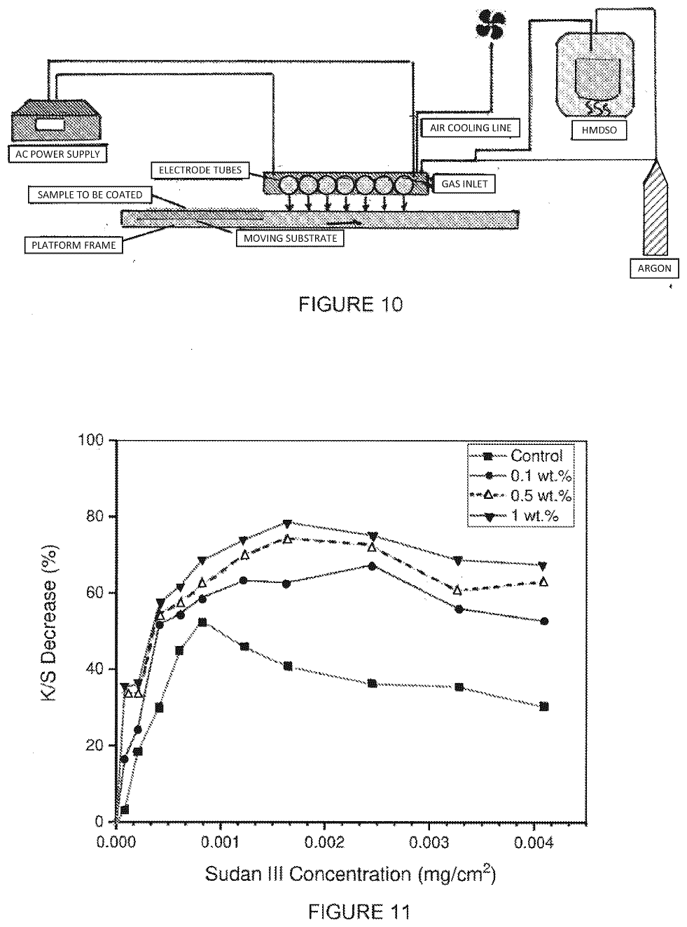

In the experimental setup shown in FIG. 10, a superhydrophobic coating created on a cotton and polyester substrate using a mixture of TiO₂ nanoparticles and PFDTS. TiO₂ nanoparticles may provide nanoroughness to the surface and also enhance the antibacterial activities due to their photocatalytic activity.

The water contact angle (WCA) of the cotton substrate surface was 162.78° after a 10 minute HMDSO plasma treatment, while 1 wt. % TiO₂-coated substrate achieved 171.31° after a 10 minute HMDSO plasma treatment, indicating good superhydrophobicity. Longer treatment periods increased the silicon compound concentration, as determined by ATR-FTIR. Prior to and after light exposure of 21600 kj/m2 for 24 hours, the K/S value of samples coated with 1 wt. % TiO₂ decreased by 75.18%. HMDSO plasma-treated 1 wt. % TiO₂ exhibited identical degradation rates, indicating that HMDSO plasma deposition on substrate surface had no negative effect on photocatalytic activity.

After 2000 or 5000 Martindale rubs, the WCA values of the HMDSO plasma-treated substrate samples decreased to around 140 degrees, which is still extremely hydrophobic. HMDSO plasma deposition on the substrate surface considerably aided in the fixation of nanoparticles after washing and the conservation of the coating's original photocatalytic action after 40 minutes and 100 minutes of ultrasonication water bathing.

Self-cleaning fabric, substrates and surfaces can keep their inherent texture and tactility. By avoiding regular washing, clothing modified by self-cleaning particles to maintain a clean or odour-reduced functionality.

The wettability of a surface when a water droplet comes into touch with it is determined by the intermolecular interactions at the three-phase boundary (liquid, solid and air). The angle of contact between the solid/liquid and liquid/air interfaces determines the nature of the interaction. The contact angle is an important aspect in determining whether a surface is hydrophobic or wettable. If the WCA is less than 90 degrees, the surface is termed hydrophilic, and water may form a thin film across the surface area and thoroughly wet the surface. In contrast, when the CA is greater than 150, surfaces are considered to be superhydrophobic, and water assumes a spherical shape and rolls off readily from a slightly inclined surface. In addition, if the CA is between 90 and 150 degrees, the surface will be classified as hydrophobic.

The superhydrophobic surface is greatly influenced by the topography of the surface. The microstructure of superhydrophobic coating comprises of bumps and rough features. Therefore, it is possible to acquire a greater value for water contact angle, which indicates a smaller interfacial area between the water droplet and the surface. Consequently, the surface has less surface adhesion. In addition, the microstructure of a superhydrophobic surface is significantly smaller than that of dust or impurities. The self-cleaning mechanism of TiO₂ particles may be a photocatalytic self-cleaning mechanism. These mechanisms are active with the presence of UV radiation, such as UV light and with the presence of oxygen.

process refers to the accelerated photoreaction in the presence of a catalyst. The process will use the photoactive substances to trigger light-activated catalytic purification functions through chemical alteration of the surface. The photocatalytic substances decompose the organic pollution molecules by utilization of the sunlight. By utilising sunlight, photocatalytic substances decompose the organic pollution molecules. Soil, contaminants, and microorganisms are examples of organic pollutants.

Photocatalytic self-cleaning fabrics use a variety of semiconducting materials, including titanium dioxide (TiO₂), zinc oxide (ZnO), and silica (SiO₂), among others. Nanotechnology is applied to the treatment of textiles because nanoparticles have a high ratio of surface area to volume and high energy. By implying self-cleaning surfaces, nanoparticle semiconducting materials provide textiles with a greater commercial and aesthetic value.

TiO₂ has superior optoelectronic properties, low-cost production, non-toxicity, and environmental friendliness compared to other semiconductors. There are three distinct crystalline forms of TiO₂: anatase, rutile, and brookite. The rutile phase is the most stable of these three phases, whereas the other two phases are metastable. The metastable phases can transform irreversibly into the rutile phase at elevated temperatures. TiO₂ is a promising photocatalytic hydrophilic material that is predominantly composed of rutile and anatase phases. In addition, it is well known that the industrial photocatalyst Degussa P-25 TiO₂ nanoparticles, composed of 70% anatase and 30% rutile, has excellent photocatalytic activity. TiO₂ can be irradiated with an energy source that exceeds its bandgap (≥3.2 eV)).

It will be appreciated that a combination of hydrophobic functionality and self-cleaning properties may be utilised to provide for an improved stain resistant surface. In the first instance the hydrophobic coatings may provide for a surface energy sufficient to repel water or other liquids, and preferably also repel oils. Any fluids or stain causing materials penetrating through to the surface of the substrate may then be removed by self-cleaning properties of the TiO₂ with exposure to a UV light source.

While it may be preferred that the application of particles to a substrate is during a PECVD process, it may be beneficial to apply the particles with a dip process, spray process, or other process known within the art such that more than one or more sides of the substrate are coated. It will be appreciated that a solution, such as a solvent, with the particles may be evaporated before a polymer coating is applied with a CVD process, or PECVD process, such that the solution is absent from the surface of the substrate and the particles remain. It will be appreciated that references herein to ‘particles’ may be replaced with ‘pigments’. Pigments may include colourants which are natural or synthetic materials and may be ground to a pre-determined size. Alternatively, it may be beneficial to provide for a solution which comprises a double bond such that effective polymerisation of the solution may be enacted and the solution is polymerised with the particles being embedded. This may be preferred as the drying of a solution may agglomerate or reduce the evenness of the dispersion of particles applied to a substrate.

Preferably, with an increased weight percentage of the TiO₂, the self-cleaning performance may be improved. Preferably, the weight percentage of the TiO₂ relative to a solution it is dispersed within will be in the range of 0.1% by weight to 5% by weight. It may be desirable to have a concentration of TiO₂ in the range of 0.5% by weight to 3% by weight for textiles.

In another embodiment, increasing the weight percentage of the TiO₂ may reduce the hydrophobic performance of the coating, particularly after UV exposure. This may be desirable for substrates which are utilised in UV exposure sensing application as the hydrophobic performance of a substrate may be tested to determine whether said substrate has been exposed to UV light. This may have utility for packaging which is sensitive to UV light or exposure to elevated temperatures.

Referring to FIG. 10 there is shown an embodiment of a simplified system which may be used to apply a coating with a particle embedded within the final coating. The system comprises a plasma treatment module and a plasma region in which the plasma coating occurs. The sample to be treated with the experimental setup was supplied with a polymer produced from HMDSO monomer formed in an argon plasma gas.

Referring to FIG. 11, there is shown another embodiment of a K/S change in colour relative to a first measured colour. The greater the K/S % decrease the more colour may be changed. In this embodiment, the Figure illustrates that the K/S decrease % is higher for an increase in substrates with a higher weight percentage of TiO₂ applied thereto. As such, a stain may be removed more readily.

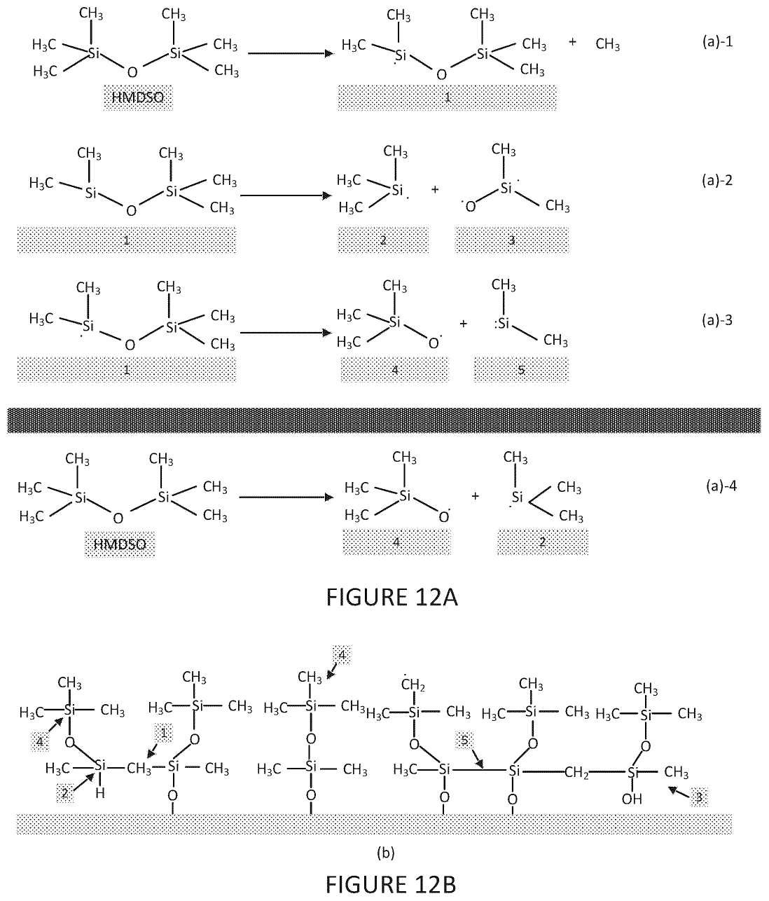

It is worthwhile to discuss the mechanism of the fundamental reaction to determine functional groups are formed. The molecular structure of hexamethyldisiloxane (HMDSO) and its possible fragmentation pathways under plasma action are depicted in FIGS. 12A and 12B. As shown in FIGS. 12A and 12B, ion bombardment generated by charge accumulation eliminated lateral groups and chain terminations such as H or CH₃. Stretching of the Si—O vibration in Si—O—Si as showed reveals the presence of a Si(CH₃)₂ chain propagation unit. By directly fragmenting HMDSO, plasma homogeneous polymerisation may accelerate the loss of —CH₃ groups. Under the influence of electrons, a variety of reactive fragments are generated, which could react further in the plasma phase to generate groups with a higher molecular weight than HMDSO. Although plasma phase reactions are homogeneous, plasma surface reactions are heterogeneous. As illustrated in FIG. 12B, chain interconnection can occur via Si—CH₂—Si (point 1 in FIG. 12B), Si—Si (indicated by 5) and Si—O groups (point 5) groups. It was demonstrated that the absence of H may facilitate the joining of adjacent chains. All of the suggested alternatives, however, included a decrease in the quantity of CH3 in the film. The absorption of O-H group by pendant bonds (FIG. 12B point 3) prevents chain reticulation. Moreover, when chain crosslinking becomes conceivable, which depends on the radical concentration and closeness, dangling bonds remain active and react with atmospheric groups when the sample is exposed to air. This mechanism partially explains the occurrence of Si—OH functional groups in the structure of organosilicon. O—H incorporation during coating deposition may also be attributable to the environment in the device chamber and the presence of oxygen in the precursor molecule (homogeneous reactions).

The experimental processes in research, which contain two steps of the approach for producing self-cleaning coatings. In the initial phase, samples were immersed in a TiO₂(P25)-Ethanol solution (3 distinct concentrations: 0.1 wt. %, 0.5 wt. %, and 1 wt. %) bathed in ultrasonication water at a bath ratio of 1:30. The superhydrophobic coating was then manufactured using an atmospheric pressure plasma coating system with DBD configuration, 300V, 130 kHz, 40 LPM of argon gas flow, and 1.0 L/min of HMDSO gas flow, with HMDSO remaining heated at 30 degrees Celsius. Samples were treated for 1 minute, 3 minutes, 5 minutes, and 10 minutes, respectively.

For surface chemical composition and morphology, SEM, XRD, and ATR-FTIR analyses were conducted. Ultrasonication effectively dispersed TiO₂ nanoparticles in ethanol, and dip coating in ultrasonicating solution successfully produced a coating with a uniform distribution for textiles, as proven by SEM. XRD diffractogram verified a textile with polyester characteristic peaks and applied TiO₂ particles of anatase and rutile phases. It also indicates that the strength of the characteristic peak increased as the sample's content of TiO₂ nanoparticles increased.

For the investigation of superhydrophobic properties, water contact angles (WCA) were measured using a tensiometer. Pristine polyester exhibits hydrophobic feature, while with increasing weight percentage of TiO₂ nanoparticle in ethanol concentration, the hydrophilicity of coated fabric surfaces was seen to increase. With increasing HMDSO plasma treatment time, the WCA of textile surface reached 162.78 degrees after 10 minutes of HMDSO plasma treatment, and 171.31 degrees of TiO₂ coated textile after 10 minutes of HMDSO plasma treatment. SEM images indicated that the HMDSO plasma TiO₂ coated samples showed thinner and smaller agglomerates, which increases surface toughness and superhydrophobicity. In addition, the concentration of —CH₃ and Si-groups on the surface of polyester treated with HMDSO plasma is higher, and the silicon compound content increased with longer treatment times, which also contributed to its superhydrophobic properties.

In order to assess the effectiveness of photocatalytic self-cleaning, samples were coloured with Sudan III-Ethanol. After 24 hours of exposure to a sunlight simulator It can be concluded that under a light exposure of 21600 kj/m2 for 24 hours, the K/S value of samples coated with 1 wt. % TiO₂ reduced by 75.18% prior to and after exposure to light, indicating the strongest self-cleaning performance among all concentrations and it displayed. Under same light exposure rates, HMDSO plasma-treated 1 wt. % TiO₂ exhibited identical degradation rates, indicating that HMDSO plasma deposition on textile surface had no detrimental influence on photocatalytic activity.

To assess the durability of the self-healing coating, the superhydrophobic coating was subjected to mechanical testing using the Martindale Test for 2000 and 5000 rubs, as well as exposed to chemical solution and UV irradiation. The mass of TiO₂-coated samples and HMDSO plasma-treated TiO₂-coated samples did not change appreciably during the Martindale Tester-provided mechanical abrasion test. After 2000 or 5000 rubs, the WCA values of the HMDSO plasma-treated textile samples reduced slightly to values around 140 degrees, which is still superhydrophobic. SEM surface morphology analysis revealed that the rising superhydrophobic surface of 5-minute HMDSO plasma-treated 1% TiO₂ coated samples was smoothed and flattened. As peeling times increased up to 5,000 times, more of the smooth topmost layer was peeled. Therefore, the WCA values and SEM pictures demonstrate that the plasma deposition of HMDSO remained intact at the surface and offer convincing evidence of the extraordinarily high adhesion between the deposition and polyester fabrics. The superhydrophobic surface treated with HMDSO plasma is mechanically robust and long-lasting. In addition, the superhydrophobic coating retains its chemical stability following interaction with ethanol. And in terms of resistance to UV irradiation, HMDSO plasma-treated textiles retain around 150 degrees of their initial superhydrophobicity after 24 hours of simulated light exposure. However, the WCA values of 1 wt. % TiO₂ textiles treated with HMDSO plasma fall dramatically from 150 degrees to 5, indicating that the samples converted from superhydrophobic to hydrophilic following exposure to simulated sunlight. ATR-FTIR data demonstrated that the functional groups of HMDSO plasma treated 1% TiO₂ coated samples remained unchanged before and after exposure to simulated light, and that the silicon concentration did not decrease. Furthermore, it is clear that the morphological properties of microscale features, such as microscale cracks and coating stripping, have not changed.

To test the adhesion of TiO₂ nanoparticles, samples coated with TiO₂ nanoparticles and samples with HMDSO plasma treated TiO₂ nanoparticles were washed for 40 and 100 minutes, respectively, in an ultrasonic water bath. As for photocatalytic effect, it can be concluded that abrasive testing with the Martindale machine had no negative impact on the removal of TiO₂ nanoparticles from the polyester samples' surface. In other words, the 1 wt. % TiO₂ coated samples treated with HMDSO plasma no longer wear or lose TiO₂ nanoparticles in this test. The photocatalytic effect remained same for the samples. However, ultrasonication water washing had a significant effect on removing TiO₂ nanoparticles from coated samples, which had a negative impact on the photocatalytic effect. It can be seen that HMDSO plasma deposition on the textile surface significantly helped to the fixing of nanoparticles after washing and the retention of the original photocatalytic function of the coating.

In this work, HMDSO atmospheric pressure plasma-treated TiO₂-coated polyester is presented for two important self-cleaning features: (a) superhydrophobic coating that repels water, and the movement of water droplets will carry away dust and impurities; and (b) self-cleaning of organic pollutants, which is accomplished by the photocatalytic property of TiO₂ nanoparticles with the action of the light. The coating process for TiO₂ nanoparticles is simple and straightforward, requiring no curing at high temperatures. Moreover, as a result of the excellent quality of HMDSO plasma deposition, the TiO₂ nanoparticles can be firmly attached to the textile surface, giving this multifunctional self-cleaning effective sustainability and durability.

### Fire Resistant or Fire Retardant

Flame retardants can reduce or inhibit flammability of the textiles by: reducing the heat generation at combustion process, reducing flammable volatiles, modifying pyrolysis reaction, forming intumescent char layer, releasing water, releasing spices like chlorinated, phosphorus, that act as an inhibitors in gas phase.

Particles which may be suitable for use for flame retardant coatings may include particles selected from the following group; Nano-clays, Carbon Nanotubes (CNT), Layered Double Hydroxide (LDH), Polyhedral Oligomeric Silsesquioxane (POSS), silicon dioxide (SiO₂), and metal nanoparticles. Optionally the SiO₂ may be nano-size. Any combination of particles may be utilised within a single coating. Optionally, a coating may be formed from several laminations such that each lamination may be a desired thickness, or contain a desired nanoparticle or pigment, or may be formed from a different material.

Suitable nano-clays may be nanoparticles of layered mineral silicates, which may be organized into several classes such as montmorillonite (MMT), and halloysite depending on chemical composition and morphology.

Metal Nanoparticles may also be metal based nanoparticles or oxides such as titanium dioxide (TiO₂), Zinc Oxide (ZnO), Aluminium oxide (Al2O3), for example.

It may be preferred that the thickness of the coating applied is at least 100 nm in thickness. It may be more preferred to select a coating in the range of 100 nm to 100 micron for a fire-retardant treatment or coating.

Preferably the char yield of the substrate is improved with the inclusion of a fire-retardant coating. Coatings may preferably include particles such as fine particles or nano particles. After application of a coating a char yield test preferably exhibits an improvement of at least 1% increased char yield relative to a substrate without said treatment.

The thickness of the coatings may be in the range of 50 nm to 900 micron. It may be more desirable to provide for a coating which is in the range of 150 nm to 900 nm. Preferably, the thickness of the coating to the particle size is in the range of 1:1 to 1:500, and more preferably, the thickness range of 1:2 to 1:200. It will be appreciated that the average thickness of the coating may be relative to the diameter of the particle within the coating.

It may be preferred that the particles within the coating are generally uniform in diameter or size. It will be appreciated that a distribution of particle sizes may be supplied within the coating, wherein the distribution may comprise a size of particle at in a known size range and the remaining particles are larger or smaller than the known size range. For example, the particles within the coating may have a known particle size of 80% by volume with the remaining 20% of particles being of a size smaller or larger than the known particle size range. In another example, the particles within the coating may have a known particle size of 80% by weight with the remaining 20% of particles being of a size smaller or larger than the known particle size range.

Optionally, the particle coatings applied provide for a flame retardant coating, or may be use in combination with a flame retardant coating which has been applied via a chemical vapour deposition process. Preferably, any such deposition process is a plasma enhanced chemical vapour deposition process.

The particles for the flame retardant coating may be applied in a lamination of the coating, or may be provided uniformly throughout the coating.

Particles may be deposited on the surface of the substrate to be coated with a functional coating, or may be provided at the same time as the functional coating is applied to the substrate.

It is preferred that the thickness of the coating, or the build-up of coating at the contact end of the particle, is sufficient to embed the particle or fix the particle in a desired position. The thickness of the coating thickness may extend at least 5% of the height of the particle. Preferably, the particle is encapsulated by the coating.

Siloxanes may be utilised for a portion of the coating, such that the flame retardancy of the particles is supplemented by the coating.

Particle sizes which may be suitable for the present disclosure may be in the range of 1 nm to 900 micron. More preferably, the range of particle sizes desirably used within a coating may be 10 nm to 200 micron.

Fixation of the particle may be desired in some applications where a single use of an article 1 may be preferred. In these cases embedding or thickness of the coating may be less important relative to the fixation or thickness of the coating which requires an improved durability requirement or will be used more than once. For example, clothing with a coating applied to a substrate of said clothing may be used multiple times, and therefore the durability requirements are likely to be higher. Further, if a pigment is supplied to an article, the pigment is adapted to provide a colour, or colour range, to the article 1. This may be of particular advantage for clothing and it may therefore be desired to improve the colourfastness of the clothing by permanent fixation of the pigment to the article 1.

Although the invention has been described with reference to specific examples, it will be appreciated by those skilled in the art that the invention may be embodied in many other forms, in keeping with the broad principles and the spirit of the invention described herein.

The present invention and the described preferred embodiments specifically include at least one feature that is industrial applicable.

1. A coating for an article, the coating comprising;
an upper side and a lower side
the coating being applied to at least one surface of the article; and wherein the coating is formed from a monomer and a nanoparticle which have passed through a plasma.

2. The substrate as claimed in claim 1, wherein the monomer is at least partly polymerised when introduced into the plasma.

3. The substrate as claimed in claim 1, wherein the nanoparticle and the monomer are a dispersion which is atomised before being introduced into the plasma.

4. The substrate as claimed in claim 1, wherein the monomer and the nanoparticle are passed through a plasma before being deposited onto the article.

5. The substrate as claimed in claim 1, wherein more than one species of nanoparticle is within the coating.

6. The substrate as claimed in claim 1, wherein the upper side of the coating is exposed to atmosphere.

7. The substrate as claimed in claim 1, wherein the upper side of the coating is adapted to be in contact with one or more pathogens.

8. The substrate as claimed in claim 1, wherein the nanoparticle has at least one of a pathogen inhibiting property, and an oligodynamic property.

9. A method for treating an article with a pathogen inhibiting layer, the method comprising;
positioning an article relatively below a treatment module;
purging local atmosphere between the article and the treatment module;
supplying a plasma fluid to an electrode region of the treatment module, the electrode region comprising two or more electrodes;
igniting a plasma gas to form a plasma in the electrode region; and supplying at least one of a monomer and a nanoparticle to the plasma in the electrode region, such that the monomer is polymerised by the plasma and the nanoparticles being fixed to the article by polymerisation of the monomer as it forms a coating on the article.

10. The method as claimed in claim 9, wherein the nanoparticles are adapted release ions to interfere with the persistence of a pathogen contacting the coating.

11. The method as claimed in claim 9, wherein the nanoparticles are distributed throughout the thickness of the coating.

12. The method as claimed in claim 9, wherein the treatment module identifies an article below the electrodes and activates electrodes corresponding to the size of the article.

13. The method as claimed in claim 9, wherein the nanoparticles are carried by a carrier fluid to the article.

14. The method as claimed in claim 9, wherein a gas aperture ejects the monomer and nanoparticle into the plasma region and onto the article.
